(19) United States
(12) Patent Application Publication
(10) Pub. No.: US 2026/0182172 A1
(43) Pub. Date: Jun. 25, 2026

(54) Display Substrate and Display Device

(71) Applicant: BOE Technology Group Co., Ltd., Beijing (CN)

(72) Inventors: Tian Dong, Beijing (CN); Jiangnan Lu, Beijing (CN)

(73) Assignee: BOE Technology Group Co., Ltd., Beijing (CN)

(21) Appl. No.: 18/729,080

(22) PCT Filed: Mar. 1, 2023
(86) PCT No.: PCT/CN2023/079137

§ 371 Date: Jul. 15, 2024

(51) Int. Cl. H10K 59/131; H10K 59/121

(52) U.S. Cl. CPC H10K 59/131; H10K 59/1213; H10K 59/1216

(57) ABSTRACT

A display substrate and a display device are provided, which includes a pixel unit, the display substrate includes a semiconductor layer, a first metal layer, a second metal layer and a first conductive layer, the first metal layer includes a first reset control signal line and a gate signal line; the second metal layer includes a first initialization signal line and a second initialization signal line; the first conductive layer includes a first connection structure and a second connection structure, a first end of the first connection structure is electrically connected with the second initialization signal line and the first connection structure extends in the second direction, a first end of the second connection structure is electrically connected with the first initialization signal line and the second connection structure extends in the second direction; the semiconductor layer includes a first connection part.

### TECHNICAL FIELD

Embodiments of the present disclosure relate to a display substrate and a display device.

### BACKGROUND

With the continuous development of display technology, active-matrix organic light emitting diode (AMOLED) display technology has been more and more used in mobile phones, tablet computers, digital cameras and other display devices because of its advantages of self-luminescence, wide viewing angle, high contrast, low power consumption and high response speed.

### SUMMARY

Embodiments of the present disclosure relate to a display substrate and a display device, which can reduce longitudinal crosstalk by arranging an orthographic projection of a first connection part on the base substrate between an orthographic projection of a first connection structure on the base substrate and an orthographic projection of a second connection structure on the base substrate in a first direction.

At least one embodiment of the present disclosure provides a display substrate, the display substrate includes: a base substrate; and a pixel unit, located on the base substrate and including a pixel circuit, in which the pixel circuit comprises a first reset transistor; the display substrate further comprises a semiconductor layer, a first metal layer, a second metal layer and a first conductive layer which are stacked on the base substrate, the first metal layer comprises a first reset control signal line and a gate signal line extending in a first direction and arranged in a second direction, and the first direction and the second direction intersect with each other; the second metal layer comprises a first initialization signal line and a second initialization signal line extending in the first direction and arranged in the second direction; the first conductive layer comprises a first connection structure and a second connection structure spaced apart from each other, a first end of the first connection structure is electrically connected with the second initialization signal line and the first connection structure extends in the second direction, and a first end of the second connection structure is electrically connected with the first initialization signal line and the second connection structure extends in the second direction; the semiconductor layer comprises a first connection part, in the second direction, an orthographic projection of the first connection part on the base substrate is located between an orthographic projection of the first reset control signal line on the base substrate and an orthographic projection of the gate signal line on the base substrate, and one end of the first connection part is electrically connected with a first electrode of the first reset transistor and the first connection part extends in the second direction; in the first direction, an orthographic projection of the first connection part on the base substrate is located between an orthographic projection of the first connection structure on the base substrate and an orthographic projection of the second connection structure on the base substrate.

For example, in the display substrate provided by at least one embodiment of the present disclosure, the second metal layer comprises a shielding block, and an orthographic projection of at least part of the shielding block on the base substrate overlaps with the orthographic projection of the first connection part on the base substrate.

For example, the display substrate provided by at least one embodiment of the present disclosure, further comprises a second conductive layer on a side of the first conductive layer away from the base substrate, the second conductive layer comprises a data line extending in the second direction, and the data line is configured to provide a data signal to the pixel circuit, and the pixel unit comprises two adjacent pixel units located in a same column, and two adjacent data lines are respectively connected with the two adjacent pixel units, and orthographic projections of the two adjacent data lines on the base substrate overlap with an orthographic projection of each of the two adjacent pixel units located in the same column on the base substrate.

For example, in the display substrate provided by at least one embodiment of the present disclosure, the shielding block comprises a first sub-shielding block extending in the second direction and a second sub-shielding block extending in the first direction, and an orthographic projection of the first sub-shielding block on the base substrate overlaps with an orthographic projection of the first connection part on the base substrate, and an orthographic projection of the second sub-shielding block on the base substrate overlaps with an orthographic projection of the data line on the base substrate.

For example, in the display substrate provided by at least one embodiment of the present disclosure, the pixel circuit further comprises a threshold compensation transistor, the threshold compensation transistor is a double-gate type thin film transistor, and the orthographic projection of the second sub-shielding block on the base substrate overlaps with an orthographic projection of a conducted active layer between two gate electrodes of the threshold compensation transistor on the base substrate.

For example, in the display substrate provided by at least one embodiment of the present disclosure, a first overlapping area of the orthographic projection of the first sub-shielding block on the base substrate and the orthographic projection of the first connection part on the base substrate is larger than a second overlapping area of the orthographic projection of the second sub-shielding block on the base substrate and the orthographic projection of the conducted active layer between the two gate electrodes of the threshold compensation transistor on the base substrate.

For example, in the display substrate provided by at least one embodiment of the present disclosure, two rows of pixel units in the second direction and four columns of pixel units arranged in sequence in the first direction form a repeating unit, and the pixel unit in a first row and a first column and the pixel unit in the first row and a second column form a first pixel unit group; the pixel unit in the first row and a third column and the pixel unit in the first row and a fourth column form a second pixel unit group; the pixel unit in a second row and the first column and the pixel unit in the second row and the second column form a third pixel unit group; the pixel unit in the second row and the third column and the pixel unit in the second row and the fourth column form a fourth pixel unit group, the first pixel unit group and the second pixel unit group are symmetrical about a straight line extending in the second direction, and the third pixel unit group and the fourth pixel unit group are symmetrical about a straight line extending in the second direction.

For example, in the display substrate provided by at least one embodiment of the present disclosure, a planar shape of the shielding block in the first pixel unit group is an inverted “L” shape, and a planar shape of the shielding block in the second pixel unit group is an “L” shape; a planar shape of the shielding block in the third pixel unit group is an “L” shape, and a planar shape of the shielding block in the fourth pixel unit group is an inverted “L” shape.

For example, in the display substrate provided by at least one embodiment of the present disclosure, a gap exists between two adjacent shielding blocks in the first pixel unit group and the second pixel unit group, and a connection block and a power supply voltage signal line are arranged in the gap, the connection block and the power supply voltage signal line are electrically connected, the connection block and the two adjacent shielding blocks are arranged in the same layer, and spaced from each other.

For example, in the display substrate provided by at least one embodiment of the present disclosure, second sub-shielding blocks of two adjacent shielding blocks in the third pixel unit group and the fourth pixel unit group are connected with each other.

For example, in the display substrate provided by at least one embodiment of the present disclosure, an orthographic projection of at least part of the first sub-shielding block on the base substrate is located between the orthographic projection of the first connection structure on the base substrate and the orthographic projection of the second connection structure on the base substrate.

For example, in the display substrate provided by at least one embodiment of the present disclosure, the shielding block comprises a first shielding part extending in a straight line in the second direction, and a second shielding part and a third shielding part extending in zigzag lines, and the second shielding part and the third shielding part are connected at an end position of the first shielding part close to the second shielding part, and the second shielding part and the third shielding part form an accommodating space so that a part of the first connection part is in the accommodating space, and an orthographic projection of another part of the first connection part on the base substrate overlaps with an orthographic projection of the first shielding part on the base substrate.

For example, in the display substrate provided by at least one embodiment of the present disclosure, the pixel circuit further comprises a threshold compensation transistor, the threshold compensation transistor is a double-gate type thin film transistor, and an orthographic projection of the third shielding part on the base substrate overlaps with an orthographic projection of a conducted active layer between two gate electrodes of the threshold compensation transistor on the base substrate.

For example, in the display substrate provided by at least one embodiment of the present disclosure, a third overlapping area of the orthographic projection of the another part of the first connection part on the base substrate and the orthographic projection of the first shielding part on the base substrate is larger than a fourth overlapping area of the orthographic projection of the third shielding part on the base substrate and the orthographic projection of the conducted active layer between the two gate electrodes of the threshold compensation transistor on the base substrate.

For example, in the display substrate provided by at least one embodiment of the present disclosure, two rows of pixel units arranged in sequence in the second direction and four columns of pixel units arranged in sequence in the first direction form a repeating unit, and the pixel unit in a first row and a first column and the pixel unit in the first row and a second column form a first pixel unit group; the pixel unit in the first row and a third column and the pixel unit in the first row and a fourth column form a second pixel unit group; the pixel unit in a second row and the first column and the pixel unit in the second row and the second column form a third pixel unit group; the pixel unit in the second row and the third column and the pixel unit in the second row and the fourth column form a fourth pixel unit group, the first pixel unit group and the second pixel unit group are symmetrical about a straight line extending in the second direction, and the third pixel unit group and the fourth pixel unit group are symmetrical about a straight line extending in the second direction.

For example, in the display substrate provided by at least one embodiment of the present disclosure, a planar shape of the third shielding part in the first pixel unit group comprises an “L” shape, a planar shape of the third shielding part in the second pixel unit group comprises an inverted “L” shape, and a part of the third shielding part in the first pixel unit group having the “L” shape and extending in the second direction is connected with a part of the third shielding part in the second pixel unit group having the inverted “L” shape and extending in the second direction.

For example, in the display substrate provided by at least one embodiment of the present disclosure, two adjacent shielding blocks of the first pixel unit group and the second pixel unit group are connected with each other, and two adjacent shielding blocks of the third pixel unit group and the fourth pixel unit group are spaced from each other; in the first pixel unit group, a first gap exists between the two adjacent shielding blocks, and an orthographic projection of at least one data line on the base substrate is located in an orthographic projection of the first gap on the base substrate; in the second pixel unit group, a second gap exists between the two adjacent shielding blocks, and an orthographic projection of at least one data line on the base substrate is located in an orthographic projection of the second gap on the base substrate; in the third pixel unit group, a third gap exists between the two adjacent shielding blocks, and an orthographic projection of at least one data line on the base substrate is located in an orthographic projection of the third gap on the base substrate; in the fourth pixel unit group, a fourth gap exists between two adjacent shielding blocks, and an orthographic projection of at least one data line on the base substrate is located in an orthographic projection of the fourth gap on the base substrate.

For example, in the display substrate provided by at least one embodiment of the present disclosure, an orthographic projection of at least part of the first shielding part on the base substrate is located between the orthographic projection of the first connection structure on the base substrate and the orthographic projection of the second connection structure on the base substrate.

For example, in the display substrate provided by at least one embodiment of the present disclosure, the second connection structure corresponding to the pixel unit in the first row and the first column and the second connection structure corresponding to the pixel unit in the second row and the first column are connected into an integrated structure to form a first column connector; the first connection structure corresponding to the pixel unit in the first row and the second column and the first connection structure corresponding to the pixel unit in the second row and the second column are connected into an integrated structure to form a second column connector; the second connection structure corresponding to the pixel unit in the first row and the third column and the second connection structure corresponding to the pixel unit in the second row and the third column are connected into an integrated structure to form a third column connector; the first connection structure corresponding to the pixel unit in the first row and the fourth column and the first connection structure corresponding to the pixel unit in the second row and the fourth column are connected into an integrated structure to form a fourth column connector; the first column connector and the third column connector are symmetrical about a straight line extending in the second direction, and the second column connector and the fourth column connector are symmetrical about a straight line extending in the second direction.

For example, in the display substrate provided by at least one embodiment of the present disclosure, the first column connector, the second column connector, the third column connector and the fourth column connector all bend and extend in the second direction, and the first column connector, the second column connector, the third column connector and the fourth column connector respectively correspond to a plurality of pixel units located in a same column.

For example, in the display substrate provided by at least one embodiment of the present disclosure, the second connection structure is electrically connected with at least two adjacent first initialization signal lines, so that the first initialization signal lines and the second connection structure intersect with each other to form a grid-like structure.

For example, in the display substrate provided by at least one embodiment of the present disclosure, the pixel circuit further comprises a driving transistor, a first power supply terminal and a storage capacitor, a first electrode plate of the storage capacitor is connected with a gate electrode of the driving transistor, and a second electrode plate of the storage capacitor is connected with the first power supply terminal, and the orthographic projection of the first connection structure on the base substrate overlaps with an orthographic projection of the second electrode plate on the base substrate.

For example, in the display substrate provided by at least one embodiment of the present disclosure, the first electrode of the first reset transistor is connected with the gate electrode of the driving transistor, a gate electrode of the first reset transistor is connected with the first reset control signal line, and a second electrode of the first reset transistor is connected with the first initialization signal line.

For example, the display substrate provided by at least one embodiment of the present disclosure, further comprises a second reset control signal line and a light emitting element, the pixel circuit further comprises a second reset transistor, a gate electrode of the second reset transistor is connected with the second reset control signal line, a first electrode of the second reset transistor is connected with the second initialization signal line, and a second electrode of the second reset transistor is connected with a first electrode of the light emitting element.

For example, in the display substrate provided by at least one embodiment of the present disclosure, the data line and the gate signal line cross each other and are insulated from each other, the gate signal line is configured to provide a scanning signal to the pixel circuit, and the pixel circuit further comprises a data writing transistor, a gate electrode of the data writing transistor is connected with the gate signal line, a first electrode of the data writing transistor is connected with the data line, and a second electrode of the data writing transistor is connected with ae first electrode of the driving transistor.

For example, the display substrate provided by at least one embodiment of the present disclosure, further comprises a light emission control signal line, the pixel circuit further comprises a first light emission control transistor and a second light emission control transistor, a gate electrode of the first light emission control transistor is connected with the light emission control signal line, a first electrode of the first light emission control transistor is connected with the first power supply terminal, and a second electrode of the first light emission control transistor is connected with the first electrode of the driving transistor; a gate electrode of the second light emission control transistor is connected with the light emission control signal line, a first electrode of the second light emission control transistor is connected with a second electrode of the driving transistor, and a second electrode of the second light emission control transistor is connected with the first electrode of the light emitting element; a first electrode of the threshold compensation transistor is connected with the second electrode of the driving transistor, and a second electrode of the threshold compensation transistor is connected with the gate electrode of the driving transistor; the gate electrodes of the threshold compensation transistor are connected with the gate signal line; the gate electrode of the driving transistor is connected with the second electrode of the threshold compensation transistor.

For example, in the display substrate provided by at least one embodiment of the present disclosure, an orthographic projection of a second end of the first connection structure on the base substrate extends in the second direction to a side of an orthographic projection of the second shielding part or the third shielding part on the base substrate close to the first shielding part.

At least one embodiment of the present disclosure further provides a display device, and the display device includes any one of the display substrates mentioned above.

### BRIEF DESCRIPTION OF DRAWINGS

In order to more clearly explain the technical solution of the embodiments of the present disclosure, the accompanying drawings of the embodiments will be briefly introduced below. Obviously, the accompanying drawings in the following description only relate to some embodiments of the present disclosure, and are not limited to the present disclosure.

FIG. 1 is a schematic diagram of a 7T1C pixel circuit provided by at least one embodiment of the present disclosure;

FIG. 2 is an operation timing chart of the pixel circuit shown in FIG. 1;

FIG. 3A is a pixel circuit diagram of a display substrate provided by at least one embodiment of the present disclosure;

FIG. 3B is a pixel circuit diagram of another display substrate provided by at least one embodiment of the present disclosure;

FIG. 4 is a schematic plan view of a semiconductor pattern in a display substrate provided by at least one embodiment of the present disclosure;

FIG. 5 is a schematic plan view of a first metal layer in a display substrate provided by at least one embodiment of the present disclosure;

FIG. 6 is a schematic diagram of an active layer, a source electrode and a drain electrode of a thin film transistor formed in a display substrate provided by at least one embodiment of the present disclosure;

FIG. 7 is a schematic plan view of a second metal layer in a display substrate provided by at least one embodiment of the present disclosure;

FIG. 8 is a schematic plan view of a display substrate provided by at least one embodiment of the present disclosure after a second metal layer is formed;

FIG. 9 is a schematic plan view of via holes formed in at least one of a first gate insulating layer, a second gate insulating layer and an interlayer insulating layer in a display substrate provided by at least one embodiment of the present disclosure;

FIG. 10 is a schematic plan view of a first conductive layer in a display substrate provided by at least one embodiment of the present disclosure;

FIG. 11 is a schematic plan view of a display substrate provided by at least one embodiment of the present disclosure after a first conductive layer is formed;

FIG. 12 is a schematic plan view of via holes formed in a passivation layer and a first planarization layer in a display substrate provided by at least one embodiment of the present disclosure;

FIG. 13 is a schematic plan view of a display substrate provided by at least one embodiment of the present disclosure after via holes are formed in a passivation layer and a first planarization layer;

FIG. 14 is a schematic plan view of a second conductive layer in a display substrate provided by at least one embodiment of the present disclosure;

FIG. 15 is a schematic plan view of a display substrate provided by at least one embodiment of the present disclosure after a second conductive layer is formed;

FIG. 16 is a schematic plan view of a semiconductor pattern in another display substrate provided by at least one embodiment of the present disclosure;

FIG. 17 is a schematic plan view of a first metal layer in another display substrate provided by at least one embodiment of the present disclosure;

FIG. 18 is a schematic diagram of an active layer, a source electrode and a drain electrode of a thin film transistor formed in a display substrate provided by at least one embodiment of the present disclosure;

FIG. 19 is a schematic plan view of a second metal layer in a display substrate provided by at least one embodiment of the present disclosure;

FIG. 20 is a schematic plan view of a display substrate provided by at least one embodiment of the present disclosure after a second metal layer is formed;

FIG. 21 is a schematic plan view of via holes formed in at least one of a first gate insulating layer, a second gate insulating layer and an interlayer insulating layer in another display substrate provided by at least one embodiment of the present disclosure;

FIG. 22 is a schematic plan view of a first conductive layer in another display substrate provided by at least one embodiment of the present disclosure;

FIG. 23 is a schematic plan view of another display substrate provided by at least one embodiment of the present disclosure after a first conductive layer is formed;

FIG. 24 is a schematic plan view of via holes formed in a passivation layer and a first planarization layer in a display substrate provided by at least one embodiment of the present disclosure;

FIG. 25 is a schematic diagram of a planar structure of a display substrate provided by at least one embodiment of the present disclosure after via holes are formed in a passivation layer and a first planarization layer;

FIG. 26 is a schematic plan view of a second conductive layer in a display substrate provided by at least one embodiment of the present disclosure;

FIG. 27 is a schematic plan view of a display substrate provided by at least one embodiment of the present disclosure after a second conductive layer is formed;

FIG. 28 is an enlarged schematic view of a part of the display substrate shown in FIG. 15; and

FIG. 29 is a schematic cross-sectional view of the display substrate shown in FIG. 28 along a line AB.

### DETAILED DESCRIPTION

In order to make the purpose, technical solution and advantages of the embodiment of the present disclosure clearer, the technical solution of the embodiment of the present disclosure will be described clearly and completely with the accompanying drawings. Obviously, the described embodiment is a part of the embodiment of the present disclosure, not the whole embodiment. Based on the described embodiments of the present disclosure, all other embodiments obtained by ordinary skilled in the art without creative labor belong to the scope of protection of the present disclosure.

Unless otherwise defined, technical terms or scientific terms used in this disclosure shall have their ordinary meanings as understood by people with ordinary skills in the field to which this disclosure belongs. The terms “first”, “second” and the like used in this disclosure do not indicate any order, quantity or importance, but are only used to distinguish different components. Similar words such as “including” or “comprising” mean that the elements or objects appearing before the word cover the elements or objects listed after the word and their equivalents, without excluding other elements or objects. Similar words such as “connected” or “connected” are not limited to physical or mechanical connection, but can include electrical connection, whether direct or indirect.

Characteristics such as “parallel”, “perpendicular” and “identical” used in this disclosure include “parallel”, “perpendicular”, “identical” and other characteristics in the strict sense, as well as “substantially parallel”, “substantially overlapping”, “substantially overlapping” and other situations that contain certain errors. For example, the above “substantially” can indicate that the difference between the compared objects is 10% of the average value of the compared objects, or within 5%. When the quantity of a component or an element is not specifically specified in the following text of the embodiment of the present disclosure, it means that the component or the element can be one or multiple, or can be understood as at least one. “At least one” refers to one or more, and “multiple” refers to at least two. The “same layer setting” in the embodiment of the present disclosure refers to the relationship between multiple film layers formed by the same material after undergoing the same step (such as a one-step patterning process). The term “same layer” herein does not always refer to multiple film layers with the same thickness or multiple film layers with the same height in the cross-sectional view.

It should be noted that, for clarity, in the drawings used to describe the embodiments of the present disclosure, the thicknesses of layers or regions are enlarged. It can be understood that when elements such as layers, membranes, regions, or substrates are referred to as located “above” or “below” another element, the element can be “directly” located “above” or “below” another element, or intermediate elements are existed.

In the technical field of organic light emitting diode display, the technical solution of dual data can solve the problem of insufficient compensation time in high-frequency display, but the technical solution of dual data has the problems of limited pixel layout space and parasitic capacitance existing between signal lines in the application of high-resolution display device. At present, there is a great demand for high frame rate active matrix organic light emitting diode (AMOLED) display substrates in the market. For example, the technical solution of dual data can increase the driving frequency on the premise of ensuring the display effect, for example, it can achieve 120 Hz driving on the premise of ensuring the display effect.

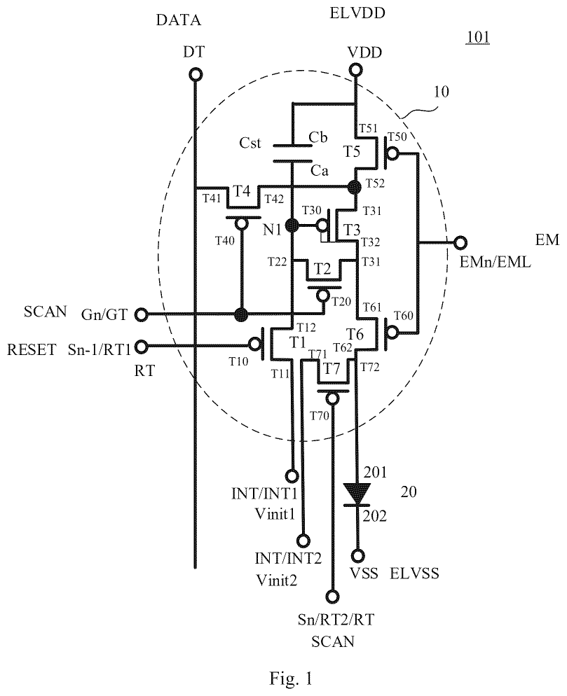

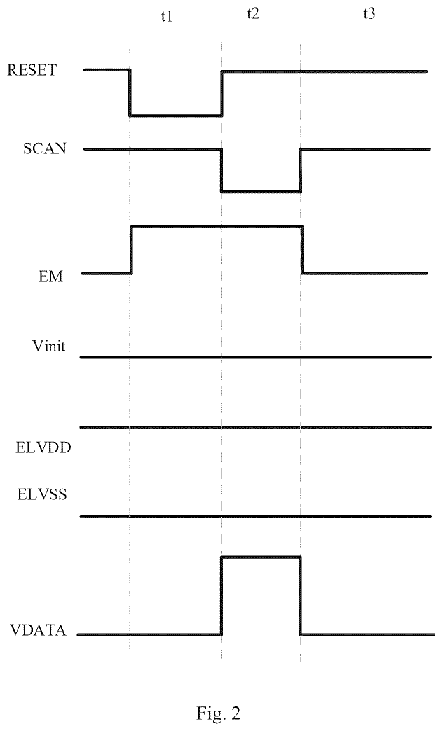

For example, FIG. 1 is a schematic diagram of a 7T1C pixel circuit provided by at least one embodiment of the present disclosure. FIG. 2 is an operation timing chart of the pixel circuit shown in FIG. 1. The pixel circuit shown in FIG. 1 can be a pixel circuit of low temperature poly-silicon (LTPS) AMOLED which is common in the related art.

For example, FIG. 1 shows a pixel circuit of a pixel unit of a display substrate provided by at least one embodiment of the present disclosure. As illustrated by FIG. 1, a pixel unit 101 includes a pixel circuit 10 and a light emitting element 20. The pixel circuit 10 includes six switching transistors (T1-T2 and T4-T7), a driving transistor T3 and a storage capacitor Cst. The six switching transistors are a first reset transistor T1, a threshold compensation transistor T2, a data writing transistor T4, a first light emission control transistor T5, a second light emission control transistor T6, and a second reset transistor T7. The light emitting element 20 includes a first electrode 201, a second electrode 202, and a light emitting functional layer located between the first electrode 201 and the second electrode 202. For example, the first electrode 201 is an anode and the second electrode 202 is a cathode. Generally, the threshold compensation transistor T2 and the first reset transistor T1 adopt a dual-gate type thin film transistor (TFT) to reduce the leakage current.

For example, as illustrated by FIG. 1, the display substrate includes a gate signal line GT, a data line DT, a first power supply terminal VDD, a second power supply terminal VSS, a light emission control signal line EML, an initialization signal line INT, a reset control signal line RT, and the like. For example, the reset control signal line RT includes a first reset control signal line RT1 and a second reset control signal line RT2. The first power supply terminal VDD is configured to provide a constant first voltage signal ELVDD to the pixel unit 101, and the second power supply terminal VSS is configured to provide a constant second voltage signal ELVSS to the pixel unit 101, and the first voltage signal ELVDD is greater than the second voltage signal ELVSS. The gate signal line GT is configured to provide a scanning signal SCAN to the pixel unit 101, the data line DT is configured to provide a data signal DATA (data voltage VDATA) to the pixel unit 101, the light emission control signal line EML is configured to provide a light emission control signal EM to the pixel unit 101, and the first reset control signal line RT1 is configured to provide a reset control signal RESET to the pixel unit 101, the second reset control signal line RT2 is configured to provide a scanning signal SCAN to the pixel unit 101, and the initialization signal line INT is configured to provide an initialization signal Vinit to the pixel unit 101. For example, the initialization signal Vinit is a constant voltage signal, and its magnitude may be between the first voltage signal ELVDD and the second voltage signal ELVSS, but the embodiment of the present disclosure is not limited thereto, for example, the initialization signal Vinit may be greater than or equal to the second voltage signal ELVSS. For example, the initialization signal line INT includes a first initialization signal line INT1 and a second initialization signal line INT2. For example, the first initialization signal line INT1 is configured to provide an initialization signal Vinit1 to the pixel unit 101, and the second initialization signal line INT2 is configured to provide an initialization signal Vinit2 to the pixel unit 101. For example, in some embodiments, the first initialization signal Vinit1 and the second initialization signal Vinit2 may be equal and both are Vinit.

For example, as illustrated by FIG. 1, the driving transistor T3 is electrically connected with the light emitting element 20, and outputs a driving current to drive the light emitting element 20 to emit light under the control of signals such as a scanning signal SCAN, a data signal DATA, a first voltage signal ELVDD, a second voltage signal ELVSS and the like.

For example, the light emitting element 20 is an organic light emitting diode (OLED), and the light emitting element 20 emits red light, green light, blue light, white light and the like under the driving of its corresponding pixel circuit 10. For example, a pixel includes a plurality of pixel units. A pixel may include a plurality of pixel units emitting light of different colors. For example, a pixel may include a pixel unit emitting red light, a pixel unit emitting green light and a pixel unit emitting blue light, but embodiments of the present disclosure are not limited thereto. The number of pixel units included in a pixel and the light emitting situation of each pixel unit can be determined as required, which is not limited by the embodiment of the present disclosure.

For example, as illustrated by FIG. 1, a gate electrode T40 of the data writing transistor T4 is connected with the gate signal line GT, a first electrode T41 of the data writing transistor T4 is connected with the data line DT, and a second electrode T42 of the data writing transistor T4 is connected with a first electrode T31 of the driving transistor T3.

For example, as illustrated by FIG. 1, a gate electrode T20 of the threshold compensation transistor T2 is connected with the gate signal line GT, a first electrode T21 of the threshold compensation transistor T2 is connected with a second electrode T32 of the driving transistor T3, and a second electrode T22 of the threshold compensation transistor T2 is connected with a gate electrode T30 of the driving transistor T3.

For example, as illustrated by FIG. 1, the display substrate further includes a light emission control signal line EML, a gate electrode T50 of the first light emission control transistor T5 is connected with the light emission control signal line EML, a first electrode T51 of the first light emission control transistor T5 is connected with the first power supply terminal VDD, and a second electrode T52 of the first light emission control transistor T5 is connected with the first electrode T31 of the driving transistor T3; a gate electrode T60 of the second light emission control transistor T6 is connected with the light emission control signal line EML, a first electrode T61 of the second light emission control transistor T6 is connected with the second electrode T32 of the driving transistor T3, and a second electrode T62 of the second light emission control transistor T6 is connected with the first electrode 201 of the light emitting element 20.

For example, as illustrated by FIG. 1, the first reset transistor T1 is connected with and configured to reset the gate electrode T30 of the driving transistor T3, and the second reset transistor T7 is connected with the first electrode 201 of the light emitting element 20 and configured to reset the first electrode 201 of the light emitting element 20. The first initialization signal line INT1 is connected with the gate electrode of the driving transistor T3 through the first reset transistor T1. The second initialization signal line INT2 is connected with the first electrode 201 of the light emitting element 20 through the second reset transistor T7. For example, the first initialization signal line INT1 and the second initialization signal line INT2 may be connected to be input the same initialization signal, but the embodiments of the present disclosure are not limited thereto. In some embodiments, the first initialization signal line INT1 and the second initialization signal line INT2 may also be insulated from each other and configured to input different initialization signals respectively.

For example, as illustrated by FIG. 1, a first electrode T11 of the first reset transistor T1 is connected with the first initialization signal line INT1, a second electrode T12 of the first reset transistor T1 is connected with the gate electrode T30 of the driving transistor T3, a first electrode T71 of the second reset transistor T7 is connected with the second initialization signal line INT2, and a second electrode T72 of the second reset transistor T7 is connected with the first electrode 201 of the light emitting element 20. For example, as illustrated by FIG. 1, a gate electrode T10 of the first reset transistor T1 is connected with the first reset control signal line RT1, and a gate electrode T70 of the second reset transistor T7 is connected with the second reset control signal line RT2.

For example, as illustrated by FIG. 1, the first power supply terminal VDD is configured to provide a first voltage signal ELVDD to the pixel circuit 10; the pixel circuit also includes a storage capacitor Cst, a first electrode plate Ca of the storage capacitor Cst is connected with the gate electrode T30 of the driving transistor T3, and the second electrode plate Cb of the storage capacitor Cst is connected with the first power supply terminal VDD.

For example, as illustrated by FIG. 1, the display substrate further includes a second power supply terminal VSS, which is connected with the second electrode 201 of the light emitting element 20.

For example, as illustrated by FIG. 2, during one frame display time period, a driving method of the pixel unit includes a first reset stage t1, a data writing, threshold compensation and second reset stage t2, and a light emitting stage t3. When the reset control signal RESET is at a low level, the gate electrode of the driving transistor T3 is reset, and when the scanning signal SCAN is at a low level, the first electrode 201 (e.g., the anode) of the light emitting element 20 is reset. For example, as illustrated by FIG. 1, when the scanning signal SCAN is at a low level, the data voltage VDATA is written, and at the same time, a threshold voltage Vth of the driving transistor T3 is obtained, and the data voltage VDATA containing the data information on the data line is stored in the capacitor Cst; when the light emission control signal line EML is at a low level, the light emitting element 20 emits light, and the voltage of the first node N1 (gate point) (light emission stability of the light emitting element 20) is maintained by the storage capacitor Cst. In the driving process of the pixel circuit 10, in the light emitting stage, the storage capacitor is used to hold the voltage signal, so that the potential at the signal holding end is kept constant, and a voltage difference is formed between the gate electrode and the source electrode of the driving transistor, thereby controlling the driving transistor to form a driving current, and further driving the light emitting element 20 to emit light.

As illustrated by FIG. 2, in the first reset stage t1, the light emission control signal EM is set as the turn-off voltage, the reset control signal RESET is set as the turn-on voltage, and the scanning signal SCAN is set as the turn-off voltage.

As illustrated by FIG. 2, in the data writing, threshold compensation and second reset stage t2, the light emission control signal EM is set as the turn-off voltage, the reset control signal RESET is set as the turn-off voltage, and the scanning signal SCAN is set as the turn-on voltage.

As illustrated by FIG. 2, in the light emitting stage t3, the light emission control signal EM is set as the turn-on voltage, the reset control signal RESET is set as the turn-off voltage, and the scanning signal SCAN is set as the turn-off voltage.

As illustrated by FIG. 2, the first voltage signal ELVDD and the second voltage signal ELVSS are both constant voltage signals, for example, the initialization signal Vinit is between the first voltage signal ELVDD and the second voltage signal ELVSS.

For example, the turn-on voltage in the embodiment of the present disclosure refers to the voltage that can conduct the first electrode and the second electrode of the corresponding transistor, and the turn-off voltage refers to the voltage that can cut off the first electrode and second electrode of the corresponding transistor. When the transistor is a P-type transistor, the turn-on voltage is a low voltage (for example, OV) and the turn-off voltage is a high voltage (for example, 5V); when the transistor is an N-type transistor, the turn-on voltage is a high voltage (for example, 5V) and the turn-off voltage is a low voltage (for example, OV). The driving waveforms shown in FIG. 2 are all explained by taking the transistors as P-type transistors. For example, the turn-on voltage is a low voltage (for example, OV) and the turn-off voltage is a high voltage (for example, 5V), but the embodiments of the present disclosure are not limited thereto.

For example, with reference to FIGS. 1 and 2, in the first reset stage t1, the light emission control signal EM is a turn-off voltage, the reset control signal RESET is a turn-on voltage, and the scanning signal SCAN is a turn-off voltage. In this case, the first reset transistor T1 is in a conducted state, while the second reset transistor T7, the data writing transistor T4, the threshold compensation transistor T2, the first light emission control transistor T5 and the second light emission control transistor T6 are in an off state. The first reset transistor T1 transmits the first initialization signal (initialization voltage Vinit) Vinit1 to the gate electrode of the driving transistor T3 and is stored by the storage capacitor Cst, which resets the driving transistor T3 and erases the data stored during the last light emission (previous frame).

In the data writing, threshold compensation and second reset stage t2, the light emission control signal EM is a turn-off voltage, the reset control signal RESET is a turn-off voltage, and the scanning signal SCAN is a turn-on voltage. In this case, the data writing transistor T4 and the threshold compensation transistor T2 are in a conducted state, and the second reset transistor T7 is in a conducted state, and the second reset transistor T7 transmits a second initialization signal (initialization voltage Vinit) Vinit2 to the first electrode 201 of the light emitting element 20 to reset the light emitting element 20. While the first light emission control transistor T5, the second light emission control transistor T6 and the first reset transistor T1 are in an off state. In this case, the data writing transistor T4 transmits the data voltage VDATA to the first electrode of the driving transistor T3, that is, the data writing transistor T4 receives the scanning signal SCAN and the data voltage VDATA and writes the data voltage VDATA to the first electrode of the driving transistor T3 according to the scanning signal SCAN. The threshold compensation transistor T2 is conducted and connects the driving transistor T3 into a diode structure, so that the gate electrode of the driving transistor T3 can be charged. After charging the gate electrode of the driving transistor T3, the gate voltage of the driving transistor T3 is VDATA+Vth, where VDATA is the data voltage and Vth is the threshold voltage of the driving transistor T3, that is, the threshold compensation transistor T2 receives the scanning signal SCAN and performs threshold voltage compensation on the gate voltage of the driving transistor T3 according to the scanning signal SCAN. At this stage, the voltage difference between the two ends of the storage capacitor Cst is ELVDD-VDATA-Vth.

In the light emitting stage t3, the light emission control signal EM is a turn-on voltage, the reset control signal RESET is a turn-off voltage, and the scanning signal SCAN is a turn-off voltage. The first light emission control transistor T5 and the second light emission control transistor T6 are in a conducted state respectively, while the data writing transistor T4, the threshold compensation transistor T2, the first reset transistor T1 and the second reset transistor T7 are in an off state respectively. The first voltage signal ELVDD is transmitted to the first electrode of the driving transistor T3 through the first light emission control transistor T5, and the gate voltage of the driving transistor T3 is maintained at VDATA+Vth, and the light emitting current I flows into the light emitting element 20 through the first light emission control transistor T5, the driving transistor T3 and the second light emission control transistor T6, so that the light emitting element 20 emits light. That is, the first light emission control transistor T5 and the second light emission control transistor T6 receive the light emission control signal EM, and control the light emitting element 20 to emit light according to the light emission control signal EM. The light emitting current I satisfies the following saturation current formula:

$${K ( Vgs - Vth )}^{2} = {K ( VDATA + Vth - ELVDD - Vth )}^{2} = {K ( VDATA - ELVDD )}^{2}$$

Where

$$K = 0.5 {µ}_{n} Cox \frac{W}{L} ,$$

μₙ is the channel mobility of the driving transistor, Cox is the channel capacitance per unit area of the driving transistor T3, W and L are the channel width and length of the driving transistor T3, respectively, and Vgs is the voltage difference between the gate electrode and the source electrode (that is, the first electrode of the driving transistor T1 in this embodiment) of the driving transistor T3.

It can be seen from the above formula that the current flowing through the light emitting element 20 is independent of the threshold voltage of the driving transistor T3. Therefore, the pixel circuit shown in FIG. 1 compensates the threshold voltage of the driving transistor T3 very well.

For example, a ratio of the duration of the light emitting stage t3 to the display period of one frame can be adjusted. In this way, the light emitting brightness can be controlled by adjusting the ratio of the duration of the light emitting stage t3 to the display period of one frame. For example, by controlling the scanning drive circuit in the display substrate or an additional drive circuit, the ratio of the duration of the light emitting stage t3 to display period of one frame can be adjusted.

For example, the embodiment of the present disclosure is not limited to the specific pixel circuit shown in FIG. 1, and other pixel circuits that can compensate the driving transistor can be adopted. Based on the description and teaching of the implementation in the embodiment of the present disclosure, other setting modes that can be easily thought of by ordinary skilled in the art without creative work are within the protection scope of the embodiment of the present disclosure.

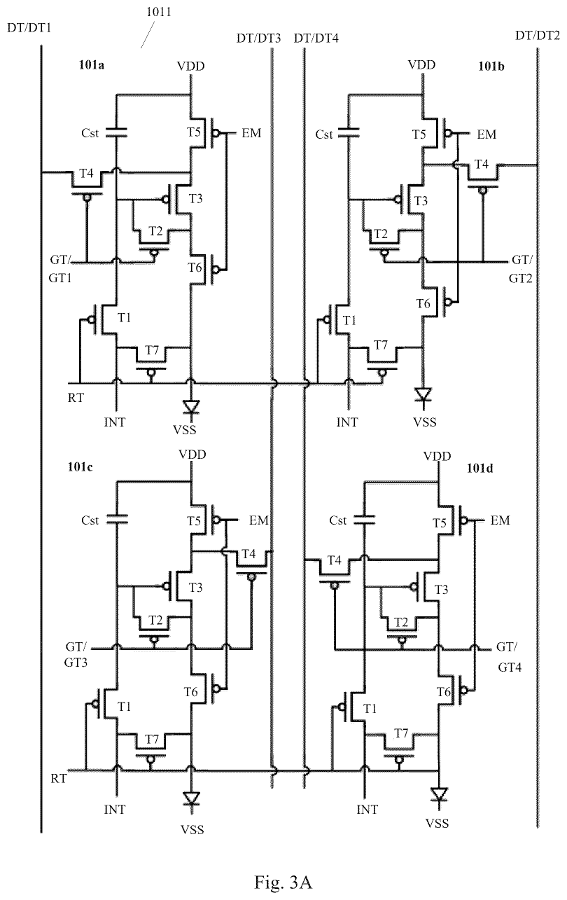

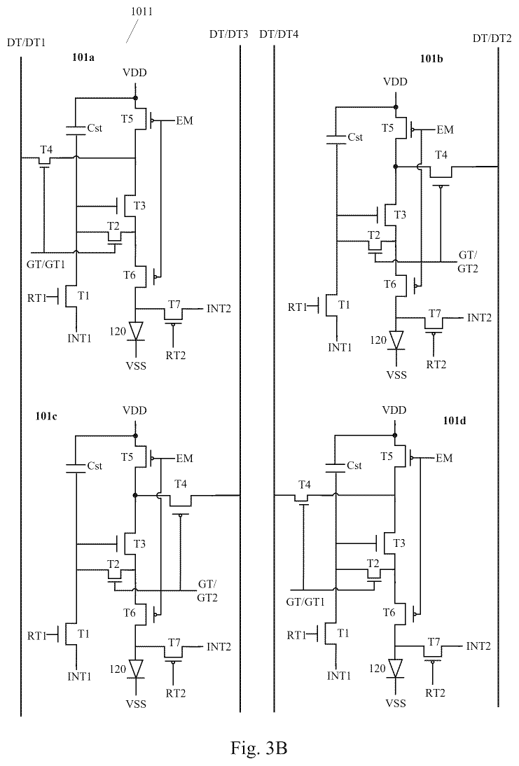

For example, FIG. 3A is a pixel circuit diagram of a display substrate provided by at least one embodiment of the present disclosure. As illustrated by FIG. 3A, the display substrate includes a base substrate 1011 on which a first pixel unit 101a, a second pixel unit 101b, a third pixel unit 101c and a fourth pixel unit 101d are arranged. And the first pixel unit 101a, the second pixel unit 101b, the third pixel unit 101c and the fourth pixel unit 101d, and the other four pixel units which are symmetrical with the whole formed by the first pixel unit 101a, the second pixel unit 101b, the third pixel unit 101c and the fourth pixel unit 101d about a straight line extending in the second direction Y constitute a repeating unit. A plurality of repeating units can form an array.

For example, the display substrate is driven by dual data lines, so that the first pixel unit 101a, the second pixel unit 101b, the third pixel unit 101c and the fourth pixel unit 101d can be independently controlled by the corresponding data lines. In the process of driving the display substrate, the first pixel unit 101a, the second pixel unit 101b, the third pixel unit 101c and the fourth pixel unit 101d are respectively lit in turn, and each pixel unit can have enough compensation time.

For example, as illustrated by FIG. 3A, the first pixel unit 101a and the second pixel unit 101b are located in the same row and adjacent columns, and the third pixel unit 101c and the fourth pixel unit 101d are located in the same row and adjacent columns. The first pixel unit 101a and the third pixel unit 101c are located in the same column and adjacent rows, and the second pixel unit 101b and the fourth pixel unit 101d are located in the same column and adjacent rows.

For example, FIG. 3B is a pixel circuit diagram of another display substrate provided by at least one embodiment of the present disclosure. One difference between FIG. 3A and FIG. 3B is that, in FIG. 3A, in the same pixel unit, the first reset transistor T1 and the second reset transistor T7 are connected with the same initialization signal line INT; in FIG. 3B, in the same pixel unit, the first reset transistor T1 and the second reset transistor T7 are connected with different initialization signal lines, the first reset transistor T1 is connected with the first initialization signal line INT1, and the second reset transistor T7 is connected with the second initialization signal line INT2.

For example, another difference between FIG. 3A and FIG. 3B is that, in FIG. 3A, in the same pixel unit, the first reset transistor T1 and the second reset transistor T7 are connected with the same reset control signal line RT to be input with the same reset control signal at the same time; in FIG. 3B, in the same pixel unit, the first reset transistor T1 and the second reset transistor T7 are connected with different reset control signal lines RT, the first reset transistor T1 is connected with the first reset control signal line RT1, and the second reset transistor T7 is connected with the second reset control signal line RT2.

For example, a first data line DT1, a second data line DT2, a third data line DT3 and a fourth data line DT4 are shown in FIGS. 3A and 3B. Referring to FIGS. 3A and 3B, a first data line DT1 is connected with a first pixel unit 101a, a second data line DT2 is connected with a second pixel unit 101b, a third data line DT3 is connected with a third pixel unit 101c, and a fourth data line DT4 is connected with a fourth pixel unit 101d.

For example, in the same pixel unit, when the first reset transistor T1 and the second reset transistor T7 are connected with the first reset control signal line and second reset control signal line, respectively, the first reset control signal line and second reset control signal line are insulated from each other to be input with corresponding reset control signals. In this case, reset control signals are input to the first reset transistor T1 and the second reset transistor T7 at different times. As mentioned above, the first reset transistor T1 is input with the reset control signal RESET in the first reset stage t1, and the second reset transistor T7 is input with the scanning signal SCAN in the data writing, threshold compensation and second reset stage t2. For example, the gate signal line GT of the present stage is connected with the reset control signal line RT of the next stage. For example, the gate signal line GT and the second reset control signal line RT2 may be electrically connected and input with the same signal at the same time.

For example, in the conventional technology, the gate electrode T30 of the driving transistor T3 is in a floating state at the light emitting stage, and is held by the storage capacitor Cst. Due to the existence of parasitic capacitance between the gate electrode and the data line, the data signal jump will be coupled to a gate signal part (the first node N1) of the driving transistor and cannot be restored to the initial state, resulting in longitudinal crosstalk. The inventor(s) of the present disclosure have noticed that it is possible to consider designing a display substrate, which includes a base substrate on which a pixel unit is arranged, the pixel unit includes a pixel circuit including a first reset transistor; the display substrate further comprises a semiconductor layer, a first metal layer, a second metal layer and a first conductive layer which are stacked on the base substrate, the first metal layer comprises a first reset control signal line and a gate signal line which extend in a first direction and are arranged in a second direction, and the first direction and the second direction intersect with each other; the second metal layer includes a first initialization signal line and a second initialization signal line extending in a first direction and arranged in a second direction; the first conductive layer comprises a first connection structure and a second connection structure which are spaced apart from each other, a first end of the first connection structure is electrically connected with the second initialization signal line and the first connection structure extends in the second direction; the semiconductor layer includes a first connection part, in the second direction, an orthographic projection of the first connection part on the base substrate is located between an orthographic projection of the first reset control signal line on the base substrate and an orthographic projection of the gate signal line on the base substrate, and one end of the first connection part is electrically connected with the first electrode of the first reset transistor and the first connection part extends in the second direction; and in the first direction, an orthographic projection of the first connection part on the base substrate is located between an orthographic projection of the first connection structure on the base substrate and an orthographic projection of the second connection structure on the base substrate. By arranging the orthographic projection of the first connection part on the base substrate between the orthographic projection of the first connection structure on the base substrate and the orthographic projection of the second connection structure on the base substrate, the longitudinal crosstalk can be reduced. The display substrate will be described in detail with reference to various single-layer structures, partial laminated structures and all layered structures in this display substrate.

Hereinafter, each layer structure of a display substrate provided by an embodiment of the present disclosure will be described with reference to FIGS. 4 to 15. It should be noted that, in the embodiment of the present disclosure, in order to clearly show the relevant structures, the insulating layers are shown in the form of via holes in the schematic diagram of the planar structure, and the insulating layers itself are treated with transparency, and in the laminated structure, all metal layers and conductive layers are treated with translucency.

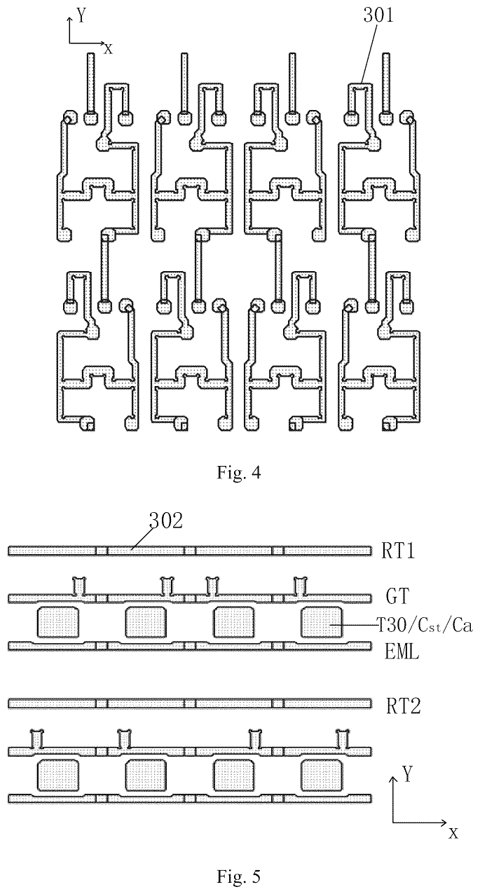

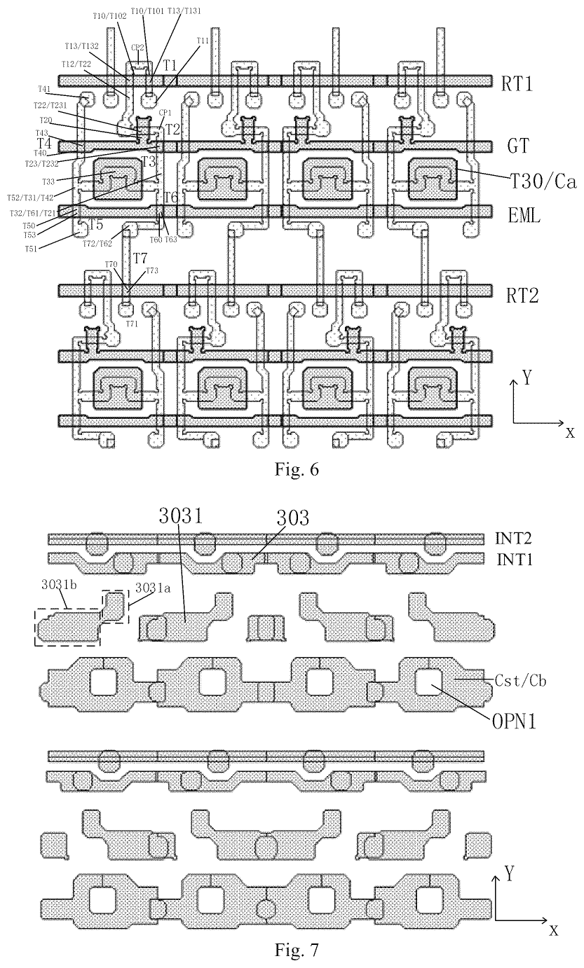

For example, FIG. 4 is a schematic plan view of a semiconductor pattern in a display substrate provided by at least one embodiment of the present disclosure. FIG. 5 is a schematic plan view of a first metal layer in a display substrate provided by at least one embodiment of the present disclosure. FIG. 6 is a schematic diagram of an active layer, a source electrode and a drain electrode of a thin film transistor formed in a display substrate provided by at least one embodiment of the present disclosure. Combined with FIGS. 4, 5 and 6, FIG. 4 shows a semiconductor layer 301, and FIG. 5 shows a first metal layer 302. For example, a first gate insulating layer (first gate insulating layer GI1, refer to subsequent cross-sectional views) is provided between the first metal layer 302 and the semiconductor layer 301. For example, the semiconductor layer 301 and subsequent various components are formed on a base substrate 1011 (shown in FIG. 1).

For example, as illustrated by FIGS. 5 and 6, the first metal layer 302 includes a first reset control signal line RT1, a gate signal line GT, a light emission control signal line EML and a second reset control signal line RT2 extending in a first direction X and arranged in a second direction Y. The first metal layer 302 also includes a first electrode plate Ca (i.e., the gate electrode T30 of the driving transistor T3 with reference to FIG. 1) of the storage capacitor Cst, the first electrode Ca of the storage capacitor Cst is located between the gate signal line GT and the light emission control signal line EML in the second direction Y. The first direction X and the second direction Y intersect with each other. The first metal layer 302 is used as a mask to dope the semiconductor layer 301, so that a region of the semiconductor layer 301 covered by the first metal layer 302 retains the semiconductor characteristics and forms an active layer, while a region of the semiconductor layer 301 not covered by the first metal layer 302 is conducted to form a source electrode and a drain electrode of the thin film transistor. FIG. 6 shows the active layer formed after the semiconductor layer is partially conducted. For example, in the embodiment of the present disclosure, the gate signal line GT of the present stage is connected with the reset control signal line of the next stage. For example, the gate signal line GT and the second reset control signal line RT2 may be electrically connected and input with the same signal at the same time.

For example, as illustrated by FIGS. 5 and 6, the first reset control signal line RT1, the gate signal line GT, the light emission control signal line EML and the second reset control signal line RT2 all extend in the first direction X.

For example, as illustrated by FIG. 6, in the manufacturing process of the display substrate, the semiconductor layer 301 is subjected to a conduction treatment by using the first metal layer 302 as a mask through a self-alignment process, for example, the semiconductor layer 301 is heavily doped by using the ion implantation process, so that a part of the semiconductor layer 301 not covered by the first metal layer 302 is made conductive, and forms a source region (first electrode T31) and a drain region (second electrode T32) of a driving transistor T3, a source region (first electrode T41) and a drain region (second electrode T42) of a data writing transistor T4, a source region (first electrode T21) and a drain region (second electrode T22) of a threshold compensation transistor T2, and a source region (first electrode T52) and a drain region (second electrode T52) of a first light emission control transistor T5, a source region (first electrode T61) and a drain region (second electrode T62) of the second light emission control transistor T6, a source region (first electrode T11) and a drain region (second electrode T12) of the first reset transistor T1, and a source region (first electrode T71) and a drain region (second electrode T72) of the second reset transistor T7. The part of the semiconductor layer 301 covered by the first metal layer 302 retains semiconductor characteristics, and forms a channel region T33 of the driving transistor T3, a channel region T43 of the data writing transistor T4, a channel region T23 of the threshold compensation transistor T2, a channel region T53 of the first light emission control transistor T5, a channel region T63 of the second light emission control transistor T6, a channel region T13 of the first reset transistor T1, and a channel region T73 of the second reset transistor T7. The channel region of each transistor constitutes an active layer.

For example, as illustrated by FIG. 6, the second electrode T72 of the second reset transistor T7 and the second electrode T62 of the second light emission control transistor T6 are integrally formed; the first electrode T61 of the second light emission control transistor T6, the second electrode T32 of the driving transistor T3 and the first electrode T21 of the threshold compensation transistor T2 are integrally formed; the first electrode T31 of the driving transistor T3, the second electrode T42 of the data writing transistor T4 and the second electrode T52 of the first light emission control transistor T5 are integrally formed; the second electrode T22 of the threshold compensation transistor T2 and the second electrode T12 of the first reset transistor T1 are integrally formed.

For example, the channel region (active layer) of the transistor adopted by the embodiment of the present disclosure may be monocrystalline silicon, polycrystalline silicon (such as low-temperature polycrystalline silicon) or metal oxide semiconductor materials (such as IGZO, AZO, etc.). In one embodiment, the transistors are all P-type low temperature polysilicon (LTPS) thin film transistors. In other embodiments, the threshold compensation transistor T2 and the first reset transistor T1 directly connected with the gate electrode of the driving transistor T3 are metal oxide semiconductor thin film transistors, that is, the materials of the channel regions of the transistors are metal oxide semiconductor materials (such as IGZO, AZO, etc.), and the metal oxide semiconductor thin film transistors have lower leakage current, which can help to reduce the gate leakage current of the driving transistor T3.

For example, the transistors adopted by the embodiments of the present disclosure may include various structures, such as a top gate electrode type, a bottom gate electrode type or a double-gate structure. In some embodiments of the present disclosure, the threshold compensation transistor T2 and the first reset transistor T1 directly connected with the gate electrode of the driving transistor T3 are double-gate type thin film transistors, which can help to reduce the gate leakage current of the driving transistor T3.

For example, as illustrated by FIG. 6, a part of the light emission control signal line EML serves as the gate electrode T50 of the first light emission control transistor T5, a part of the light emission control signal line EML serves as the gate electrode T60 of the second light emission control transistor T6, the gate electrode T10 of the first reset transistor T1 is a part of the first reset control signal line RT1, the gate electrode T70 of the second reset transistor T7 is a part of the second reset control signal line RT2, the gate electrode T40 of the data writing transistor T4 is a part of the gate signal line GT, and the gate electrode T20 of the threshold compensation transistor T2 is a part of the gate signal line GT.

For example, as illustrated by FIG. 6, the threshold compensation transistor T2 is a double-gate type thin film transistor, and includes a first channel T231 and a second channel T232, which are connected by a first conductive connection part CP1. For example, an orthographic projection of the first conductive connection part CP1 on the base substrate 1011 at least partially overlaps with an orthographic projection of a conducted active layer between the two gate electrodes T20 of the threshold compensation transistor T2 on the base substrate 1011.

For example, as illustrated by FIG. 6, the first reset transistor T1 is a double-gate type thin film transistor, and includes a first channel T131 and a second channel T132, which are connected by a second conductive connection part CP2. For example, an orthographic projection of the second conductive connection part CP2 on the base substrate 1011 at least partially overlaps with an orthographic projection of a conducted active layer between the two gate electrodes T10 of the first reset transistor T1 on the base substrate 1011.

For example, FIG. 7 is a schematic plan view of a second metal layer in a display substrate provided by at least one embodiment of the present disclosure. For example, as illustrated by FIG. 7, a second gate insulating layer is provided between the second metal layer 303 and the first metal layer 302. The second metal layer 303 includes a shielding block 3031, a first initialization signal line INT1, a second initialization signal line INT2, and a second electrode plate Cb of the storage capacitor Cst. For example, referring to FIG. 7, the first initialization signal line INT1 extends in the first direction X, and the second initialization signal line INT2 extends in the first direction X. The first initialization signal line INT1 and the second initialization signal line INT2 are arranged in the second direction Y. As illustrated by FIG. 7, the first initialization signal line INT1 and the second initialization signal line INT2 are located on the same side of the second electrode plate Cb of the storage capacitor Cst, and the first initialization signal line INT1 and the second initialization signal line INT2 are located on the same side of the shielding block 3031. As illustrated by FIG. 7, the second initialization signal line INT2, the first initialization signal line INT1, the shielding block 3031 and the second electrode plate Cb of the storage capacitor Cst are sequentially arranged in the second direction Y. The shielding block 3031 is electrically connected with the first power supply line VDD1 (located in the second conductive layer mentioned later), so that the first power supply line VDD1 provides a constant voltage for the shielding block 3031.

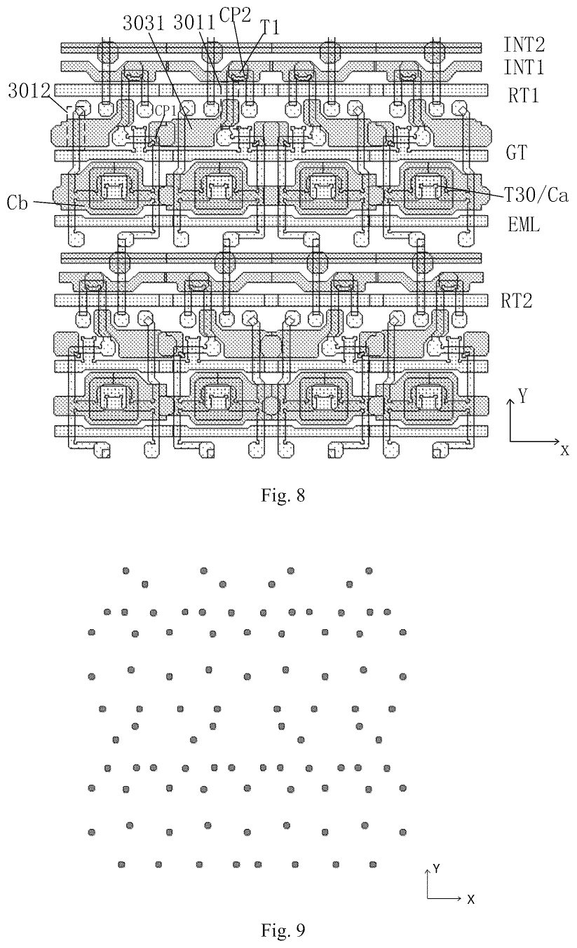

For example, FIG. 8 is a schematic plan view of a display substrate provided by at least one embodiment of the present disclosure after a second metal layer is formed. For example, in the conventional technology, the threshold compensation transistor T2 is a double-gate type thin film transistor, and the intermediate node (the first conductive connection part CP1) of the threshold compensation transistor T2 will be disturbed by the jump of the scanning signal, and the voltage will increase at the moment when the scanning signal is turned off, and the current leakage to the gate electrode of the driving transistor T3 will be intensified, which will lead to the flicker problem.

For example, in order to reduce the current leakage of the threshold compensation transistor T2, an orthographic projection of the shielding block 3031 on the base substrate 1011 at least partially overlaps with an orthographic projection of the first conductive connection part CP1 on the base substrate 1011, so that a stable capacitance is formed between the shielding block 3031 and the first conductive connection part CP1. The increase of the parasitic capacitance between the intermediate node of the threshold compensation transistor T2 and the first voltage signal ELVDD can reduce the disturbance and ameliorate the current leakage problem. For example, as illustrated by FIG. 8, the orthographic projection of the shielding block 3031 on the base substrate 1011 at least partially overlaps with the orthographic projection of the first conductive connection part CP1 on the base substrate 1011, that is, the shielding block 3031 is configured to shield the conducted active layer between the two gate electrodes of the threshold compensation transistor T2, and a capacitor (stable capacitor) is formed between the shielding block 3031 and the first conductive connection part CP1, that is, a stable capacitor is formed to reduce leakage current, thereby avoiding affecting the display effect.

For example, in the plan view shown in FIG. 7, the shielding block 3031 partially overlaps with the first conductive connection part CP1, that is, the shielding block 3031 at least partially overlaps with the conducted active layer between the two gate electrodes T20 of the threshold compensation transistor T2, and the shielding block 3031 is connected with the data line (located on the second conductive layer mentioned later), so that parasitic capacitance between the data line and the gate electrode T20 of the threshold compensation transistor T2 can be shielded to reduce longitudinal crosstalk.

For example, in the plan view shown in FIG. 8, the first initialization signal line INT1 at least partially overlaps with the second conductive connection part CP2, and a capacitor (stable capacitor) is formed between the first initialization signal line INT1 and the second conductive connection part CP2 to avoid leakage current of the first reset transistor T1 and avoid affecting the display effect.

For example, in the embodiment of the present disclosure, element A partially overlaps with element B, which refers to that a part of element A overlaps with element B, a part of element B overlaps with element A, or a part of element A overlaps with a part of element B. Element A and element B are two different elements.

For example, as illustrated by FIG. 7, the gate signal line GT extends in the first direction X, the first reset control signal line RT1 extends in the first direction X, and the shielding block 3031 is located between the gate signal line GT and the first reset control signal line RT1, so that the position of the shielding block 3031 in the second direction Y is defined.

For example, as illustrated by FIG. 7 and FIG. 8, an orthographic projection of at least part of the shielding block 3031 on the base substrate 1011 overlaps with the orthographic projection of the first connection part 3011 on the base substrate 1011. The first connection part 3011 is connected with the gate electrode T30 of the driving transistor T3, and the orthographic projection of the first connection part 3011 on the base substrate 1011 at least partially overlaps with the orthographic projection of the shielding block 3031 on the base substrate 1011, so that the shielding block 3031 shields the parasitic capacitance between the gate electrode of the driving transistor T3 and the data line, reduces the coupling influence and reduces the longitudinal crosstalk.

For example, as illustrated by FIG. 7 and FIG. 8, the shielding block 3031 includes a first sub-shielding block 3031a extending in the second direction Y and a second sub-shielding block 3031b extending in the first direction X. An orthographic projection of the first sub-shielding block 3031a on the base substrate 1011 overlaps with an orthographic projection of the first connection part 3011 on the base substrate 1011, and an orthographic projection of the second sub-shielding block 3031b on the base substrate 1011 overlaps with an orthographic projection of the data line (shown in the second conductive layer later) on the base substrate 1011. The orthographic projection of the second sub-shielding block 3031b on the base substrate 1011 is also overlapped with the orthographic projection of the conducted active layer between the two gate electrodes of the threshold compensation transistor T2 on the base substrate 1011.

For example, the material of the first connection part 3011 is the same as that of the first conductive connection part CP1. For example, the first connection part 3011 and the first conductive connection part CP1 can be made of the same film layer through the same process. For example, the material of the first connection part 3011 includes a conductive material obtained by doping a semiconductor material. For example, the material of the first connection part 3011 includes a conductive material obtained by doping polysilicon, but the embodiment of the present disclosure is not limited thereto.

For example, as illustrated by FIGS. 6, 7 and 8, the first connection part 3011 is multiplexed as the second electrode T12 of the first reset transistor T1, and an orthographic projection of the second electrode T12 of the first reset transistor T1 on the base substrate 1011 at least partially overlaps with an orthographic projection of the shielding block 3031 on the base substrate 1011. In the embodiment of the present disclosure, the first connection part 3011 is taken as the second electrode T12 of the first reset transistor T1 as an example.

For example, as illustrated by FIGS. 6, 7 and 8, orthographic projections of the first gate electrode T101 and the second gate electrode T102 of the first reset transistor T1 on the base substrate 1011 overlaps with the orthographic projections of the first channel T131 and the second channel T132 of the first reset transistor T1 on the base substrate 1011, respectively.

As illustrated by FIG. 8, the area of an orthographic projection of a part of the shielding block 3031 overlapping with the first connection part 3011 (the second electrode T12 of the first reset transistor T1) on the base substrate 1011 is larger than the area of an orthographic projection of a part of the shielding block 3031 overlapping with the first conductive connection part CP1 on the base substrate 1011.

For example, with reference to FIGS. 7 and 8, the orthographic projection of the first sub-shielding block 3031a on the base substrate and the orthographic projection of the first connection part 3011 on the base substrate 1011 have an overlapping part, and the orthographic projection of the second sub-shielding block 3031b on the base substrate 1011 and the orthographic projection of the conducted active layer between the two gate electrodes of the threshold compensation transistor T2 have an overlapping part. And a first overlapping area of the orthographic projection of the first sub-shielding block 3031a on the base substrate and the orthographic projection of the first connection part 3011 on the base substrate 1011 is larger than a second overlapping area of the orthographic projection of the second sub-shielding block 3031b on the base substrate 1011 and the orthographic projection of the conducted active layer between the two gate electrodes of the threshold compensation transistor T2 on the base substrate 1011.

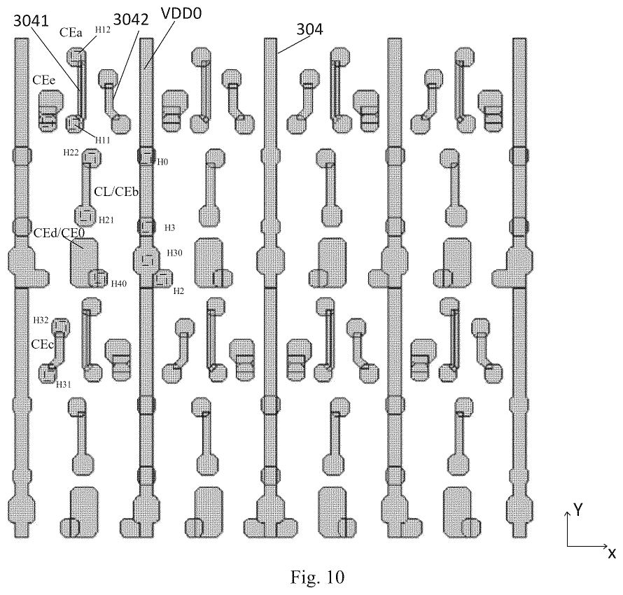

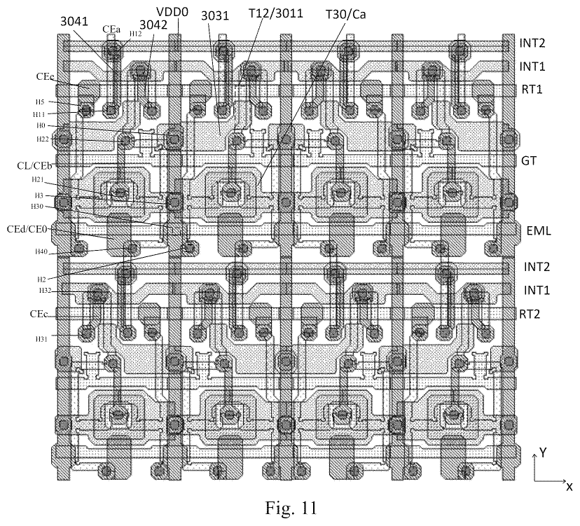

For example, FIG. 9 is a schematic plan view of via holes formed in at least one of a first gate insulating layer, a second gate insulating layer and an interlayer insulating layer in a display substrate provided by at least one embodiment of the present disclosure. FIG. 10 is a schematic plan view of a first conductive layer in a display substrate provided by at least one embodiment of the present disclosure. FIG. 11 is a schematic plan view of a display substrate provided by at least one embodiment of the present disclosure after a first conductive layer is formed.

For example, with reference to FIGS. 9 to 11, the first conductive layer 304 includes a power connection line VDD0, a connection electrode CEa, a connection electrode CEb, a connection electrode CEc, a connection electrode CEd and a connection electrode CEe. An interlayer insulating layer (for example, an interlayer insulating layer ILD) is provided between the first conductive layer 304 and the second metal layer 303.

For example, as illustrated by FIGS. 9 to 11, the first conductive layer 304 includes a first connection structure 3041 and a second connection structure 3042 spaced apart from each other. A first end of the first connection structure 3041 is electrically connected with the second initialization signal line INT2, and the first connection structure 3041 extends in the second direction Y, and a first end of the second connection structure 3042 is electrically connected with the first initialization signal line INT1 and the second connection structure 3042 extends in the second direction Y.

For example, as illustrated by FIG. 9, the first connection structure 3041 is the connection electrode CEa.

For example, as illustrated by FIGS. 7 and 9, an orthographic projection of at least part of the first sub-shielding block 3031a on the base substrate 1011 is located between the orthographic projection of the first connection structure 3041 on the base substrate 1011 and the orthographic projection of the second connection structure 3042 on the base substrate 1011.

For example, with reference to FIGS. 9 to 11, the power connection line VDD0 is electrically connected with the first electrode T51 of the first light emission control transistor T5 through a via hole H2, the power connection line VDD0 is electrically connected with the second electrode plate Cb of the storage capacitor Cst through the via holes H3 and H30, and the power connection line VDD0 is electrically connected with the shielding block 3031 through a via hole HO. One end of the connection electrode CEa is electrically connected with the second initialization signal line INT2 through a via hole H12, and the other end of the connection electrode CEa is connected with the first electrode T11 of the first reset transistor T1 through a via hole H11, so that the first electrode T11 of the first reset transistor T1 is electrically connected with the second initialization signal line INT2. One end of the connection electrode CEb is electrically connected with the second electrode T12 of the first reset transistor T1 through a via hole H22, and the other end of the connection electrode CEb is electrically connected with the gate electrode T30 of the driving transistor T3 (i.e. the first electrode plate Ca of the storage capacitor Cst) through a via hole H21, so that the second electrode T12 of the first reset transistor T1 is electrically connected with the gate electrode T30 of the driving transistor T3 (i.e. the first electrode plate Ca of the storage capacitor Cst). One end of the connection electrode CEc is electrically connected with the first initialization signal line INT1 through a via hole H32, and the other end of the connection electrode CEc is connected with the first electrode T71 of the second reset transistor T7 through the via hole H31, so that the first electrode T71 of the second reset transistor T7 is electrically connected with the first initialization signal line INT1. The connection electrode CEd is electrically connected with the second electrode T62 of the second light emission control transistor T6 through the via hole H40. The connection electrode CEd can be used to connect with the subsequent connection electrode CEf, and then electrically connected with the first electrode 201 of the light emitting element 20. The connection electrode CEe is electrically connected with the first electrode T41 of the data writing transistor T4 through a via hole H5. The connection electrode CEe is used to be connected with the data line.

For example, with reference to FIGS. 4 to 11, the semiconductor layer 301 includes a first connection part 3011. In the second direction Y, the orthographic projection of the first connection part 3011 on the base substrate 1011 is located between the orthographic projection of the first reset control signal line RT1 on the base substrate 1011 and the orthographic projection of the gate signal line GT on the base substrate 1011. One end of the first connection part 3011 is electrically connected with the first electrode T11 of the first reset transistor T1, and extending in the second direction Y. In the first direction X, the orthographic projection of the first connection part 3011 on the base substrate 1011 is located between the orthographic projection of the first connection structure 3041 on the base substrate 1011 and the orthographic projection of the second connection structure 3042 on the base substrate 1011. This design can reduce the longitudinal crosstalk. For example, the first connection part 3011 is an equipotential structure of the gate electrode of the driving transistor T3.

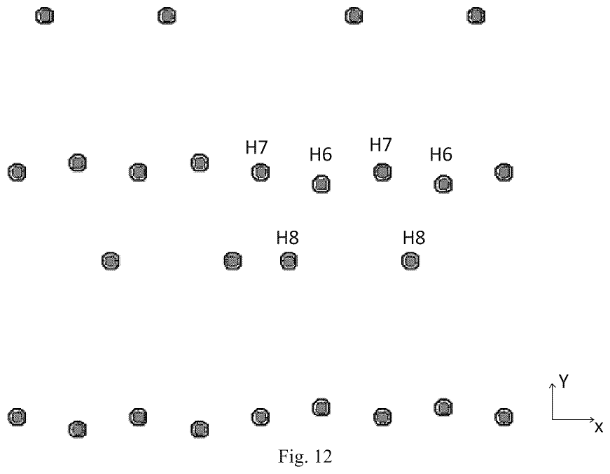

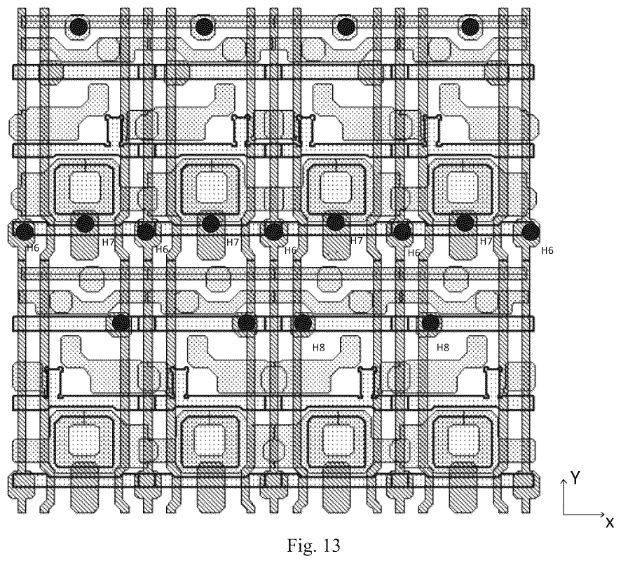

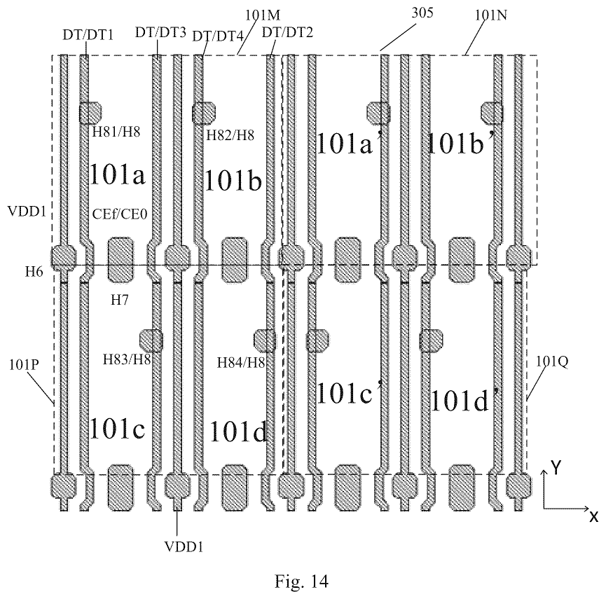

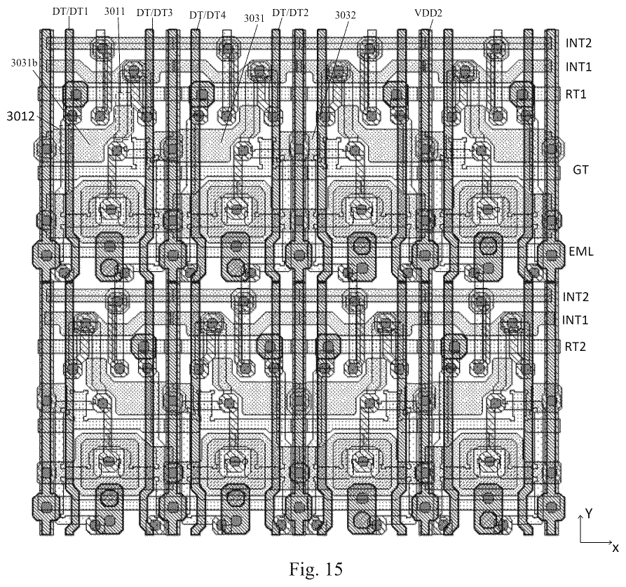

For example, FIG. 12 is a schematic plan view of via holes formed in a passivation layer and a first planarization layer in a display substrate provided by at least one embodiment of the present disclosure; FIG. 13 is a schematic plan view of a display substrate provided by at least one embodiment of the present disclosure after via holes are formed in a passivation layer and a first planarization layer; FIG. 14 is a schematic plan view of a second conductive layer in a display substrate provided by at least one embodiment of the present disclosure; and FIG. 15 is a schematic plan view of a display substrate provided by at least one embodiment of the present disclosure after a second conductive layer is formed.

For example, with reference to FIGS. 12 to 15, the second conductive layer 305 includes a data line DT, a connection electrode CEf, and a first power supply line VDD1. The data line DT extends in the second direction Y, and the data line DT is configured to provide a data signal to the pixel circuit. The pixel units include two adjacent pixel units located in the same column, and two adjacent data lines DT are connected with the two adjacent pixel units respectively, and orthographic projections of the two adjacent data lines DT on the base substrate 1011 overlap with an orthographic projection of each of the two adjacent pixel units located in the same column on the base substrate 1011. A passivation layer (passivation layer PVX, referring to the subsequent schematic cross-sectional structure) and a first planarization layer (first planarization layer PLN1, referring to the subsequent schematic cross-sectional structure) are arranged between the first conductive layer 304 and the second conductive layer 305. The first power supply line VDD1 is connected with the power supply connection line VDD0 through a via hole H6 penetrating the passivation layer and the first planarization layer, and the connection electrode CEf is connected with the connection electrode CEd through a via hole H7 penetrating the passivation layer and the first planarization layer. The data line DT is connected with the connection electrode CEe through a via hole H8 penetrating through the passivation layer and the first planarization layer, and is further electrically connected with the first electrode T41 of the data writing transistor T4. For example, the connection electrode CEf and the connection electrode CEd constitute the connection element CEO. For example, the light emitting element 20 is connected with the pixel circuit 10 through the connection element CEO. For example, the pixel circuit 10 is connected with the connection electrode CEd, the connection electrode CEd is connected with the connection electrode CEf, and the connection electrode CEf is connected with the light emitting element 20.

For example, as illustrated by FIG. 14, corresponding to the pixel unit 101a, the pixel unit 101b, the pixel unit 101c and the pixel unit 101d, via holes H8 penetrating the passivation layer and the first planarization layer include a via hole H81, a via hole H82, a via hole H83 and a via hole H84.

For example, with reference to FIG. 15, the orthographic projection of the second sub-shielding block 3031b on the base substrate 1011 overlaps with the orthographic projection of the data line DT on the base substrate 1011.

For example, as illustrated by FIG. 14, two rows of pixel units 101 arranged in the second direction Y and four columns of pixel units 101 arranged in the first direction X form a repeating unit, and the pixel unit 101 in a first row and a first column and the pixel unit 101 in the first row and a second column form a first pixel unit group 101M; the pixel unit 101 in the first row and a third column and the pixel unit 101 in the first row and a fourth column form a second pixel unit group 101N; the pixel unit 101 in a second row and the first column and the pixel unit 101 in the second row and the second column form a third pixel unit group 101P; the pixel unit 101 in the second row and the third column and the pixel unit 101 in the second row and the fourth column form a fourth pixel unit group 101Q, the first pixel unit group 101M and the second pixel unit group 101N are symmetrical about a straight line extending in the second direction Y, and the third pixel unit group 101P and the fourth pixel unit group 101Q are symmetrical about a straight line extending in the second direction Y.

For example, FIG. 14 shows a first data line DT1, a second data line DT2, a third data line DT3 and a fourth data line DT4. FIG. 14 also shows the positions of the first pixel unit 101a, the second pixel unit 101b, the third pixel unit 101c and the fourth pixel unit 101d. Actually, eight pixel units are shown in FIG. 14, and the whole composed of pixel unit 101a′, pixel unit 101b′, pixel unit 101c′ and pixel unit 101d′ is symmetrical with the whole composed of the first pixel unit 101a, the second pixel unit 101b, the third pixel unit 101c and the fourth pixel unit 101d about the Y axis (i.e. the second direction).

For example, as illustrated by FIG. 15, the planar shape of the shielding block 3031 in the first pixel unit group is an inverted “L” shape, and the planar shape of the shielding block 3031 in the second pixel unit group is an “L” shape; the planar shape of the shielding block 3031 in the third pixel unit group is an “L” shape, and the planar shape of the shielding block 3031 in the fourth pixel unit group is an inverted “L” shape.

For example, as illustrated by FIG. 15, a gap exists between two adjacent shielding blocks 3031 of the first pixel unit group 101M and the second pixel unit group 101N, and a connection block 3032 and a power supply voltage signal line VDD2 are arranged in the gap, the connection block 3032 and the power supply voltage signal line VDD2 are electrically connected, and the connection block 3032 and the shielding block 3031 are arranged in the same layer, and the connection block 3032 and the two adjacent shielding blocks 3031 are spaced from each other, that is, the connection block 3032 is not connected with the two adjacent shielding blocks 3031.

For example, in other embodiments, two shielding blocks 3031 in the first pixel unit group 101M may be connected with each other, two shielding blocks 3031 in the second pixel unit group 101N may be connected with each other, and two adjacent shielding blocks 3031 in the first pixel unit group 101M and the second pixel unit group 101N may also be connected with each other, that is, they may be connected to form an elongated shape.

For example, in one example, the second sub-shielding blocks 3031b of two shielding blocks 3031 adjacent to each other of the third pixel unit group 101P and the fourth pixel unit group 101Q are connected with each other.

For example, as illustrated by FIGS. 14 and 15, the data line DT extends in the second direction Y, and the first data line DT1, the third data line DT3, the fourth data line DT4 and the second data line DT2 are sequentially arranged in the first direction X. The fourth data line DT4 is located between the third data line DT3 and the second data line DT2. The first pixel unit 101a and the second pixel unit 101b are located in the same row and adjacent columns, and the third pixel unit 101c and the fourth pixel unit 101d are located in the same row and adjacent columns. The first pixel unit 101a and the third pixel unit 101c are located in the same column and adjacent rows, and the second pixel unit 101b and the fourth pixel unit 101d are located in the same column and adjacent rows. As illustrated by FIG. 15, the data line DT and the gate line GT cross each other and are insulated from each other.

For example, as illustrated by conjunction with FIGS. 1, 3B and 14, the first power supply line VDD1 is configured to provide the first voltage signal ELVDD to the pixel circuit 10. The first power supply line VDD1 is electrically connected with the shielding block 3031 to provide a constant voltage for the shielding block 3031. The first power supply line VDD1 is connected with the first power supply terminal VDD, and the second electrode plate Cb of the storage capacitor Cst is connected with the first power supply line VDD1. For example, the second electrode plate Cb of the storage capacitor Cst is connected with the first power supply terminal VDD through the power supply connection line VDD0 and the first power supply line VDD1.

For example, the first electrode T51 of the first light emission control transistor T5 is connected with the first power supply terminal VDD through a power supply connection line VDD0 and a first power supply line VDD1 (refer to FIGS. 6, 11 and 15).

For example, as illustrated by FIGS. 8 and 15, the display substrate includes a second connection part 3012, and the orthographic projection of the shielding block 3031 on the base substrate at least partially overlaps with an orthographic projection of the second connection part 3012 on the base substrate, so as to shield the interference between the first data signal on the first data line DT1 and the third data signal on the third data line DT3 and avoid display abnormality caused by coupling. For example, in the first pixel unit 101a and the second pixel unit 101b, the shielding block 3031 overlaps with the first conductive connection part CP1 of the threshold compensation transistor T2 of the second pixel unit 101b and the second connection part 3012 of the first pixel unit 101a. For example, the second connection part 3012 is made of the same material as the first connection part 3011. For example, as illustrated by FIGS. 6, 8 and 15, the first electrode T41 of the data writing transistor T4 is multiplexed as the second connection part 3012. In the embodiment of the present disclosure, the first electrode T41 of the data writing transistor T4 is used as the second connection part 3012 as an example, but the embodiment of the present disclosure is not limited thereto.

For example, as illustrated by FIGS. 3B, 11 and 15, the data line DT, the connection electrode CEe and the second connection part 3012 constitute a data signal part. For example, the data line DT, the connection electrode CEe and the second connection part 3012 constitute the same node. For example, the potentials on the data line DT, the connection electrode CEe and the second connection portion 3012 are the same or substantially the same. That is, the potential at each position on the data signal section is the same or basically the same. Therefore, the shielding block 3031 overlaps with the second connection part 3012, and the orthographic projection of the shielding block 3031 on the base substrate 1011 overlaps with the orthographic projection of the data line, for example, the orthographic projection of the second sub-shielding block 3031b on the base substrate 1011 overlaps with the orthographic projection of the first data line DT1 on the base substrate 1011, so that the interference between the first data signal on the first data line DT1 and the third data signal on the third data line DT3 can be shielded, and the display abnormality caused by coupling can be avoided.

For example, as illustrated by FIG. 3B, FIG. 8 and FIG. 15, the area of an orthographic projection of a part of the shielding block 3031 overlapping with the second connection part 3012 (the first electrode T41 of the data writing transistor T4) on the base substrate 1011 is larger than the area of an orthographic projection of a part of the shielding block 3031 overlapping with the first conductive connection part CP1 on the base substrate 1011. For example, the data line DT is connected with the connection electrode CEe through the via hole H8, and further connected with the second connection part 3012.

For example, as illustrated by FIG. 3B, FIG. 8 and FIG. 15, the area of an orthographic projection of a part of the shielding block 3031 overlapping with the first connection part 3011 on the base substrate 1011 is larger than the area of an orthographic projection of a part of the shielding block 3031 overlapping with the second connection part 3012 on the base substrate 1011.

For example, as illustrated by FIG. 3B and FIG. 15, the area of the orthographic projection of the part of the shielding block 3031 overlapping with the first connection part 3011 on the base substrate 1011, the area of the orthographic projection of the part of the shielding block 3031 overlapping with the second connection part 3012 on the base substrate 1011 and the area of the orthographic projection of the part of the shielding block 3031 overlapping with the first conductive connection part CP1 on the base substrate 1011 are successively reduced, but the embodiments of the present disclosure are not limited thereto.

For example, as illustrated by FIGS. 3B and 15, the orthographic projection of the shielding block 3031 on the base substrate 1011 partially overlaps with the orthographic projection of the third data line DT3 on the base substrate 1011, so that the shielding block 3031 shields the interference between the first data signal on the first data line DT1 and the third data signal on the third data line DT3, and avoids display abnormality caused by coupling.

For example, in the planar structure diagram shown in FIG. 15, one shielding block 3031 corresponds to two pixel units in the same row. As illustrated by FIG. 15, the shielding block 3031 is located between the first data line DT1 and the third data line DT3.

For example, as illustrated by FIG. 3B, FIG. 8 and FIG. 15, the orthographic projection of the first electrode T41 of the data writing transistor T4 on the base substrate 1011 at least partially overlaps with the orthographic projection of the third data line DT3 on the base substrate 1011.

For example, in the embodiment of the present disclosure, two adjacent elements refer to that the two elements are adjacent to each other, and there is no element between them, but it is not excluded that other elements other than such elements are arranged between the two adjacent elements.

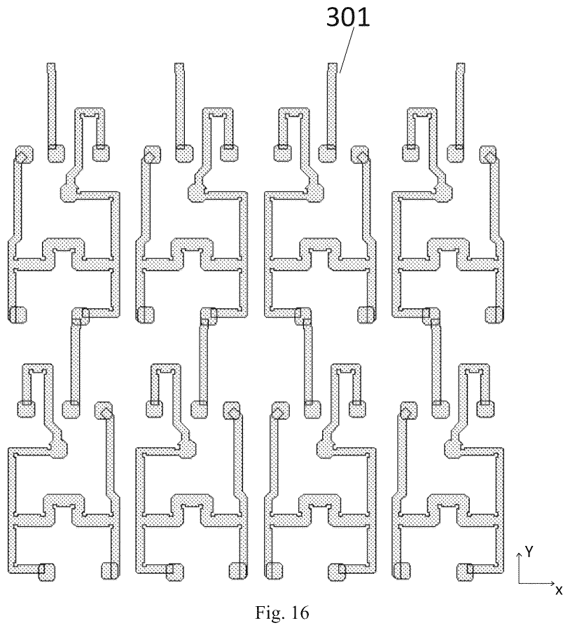

For example, each layer structure of another display substrate provided by an embodiment of the present disclosure will be described below with reference to FIGS. 16 to 27. It should be noted that in the embodiment of the present disclosure, in order to clearly show the relevant structures, the insulating layers are shown in the form of via holes in the schematic diagram of the planar structure, and the insulating layer itself are treated with transparency, and in the laminated structure, all metal layers and conductive layers are treated with translucency.

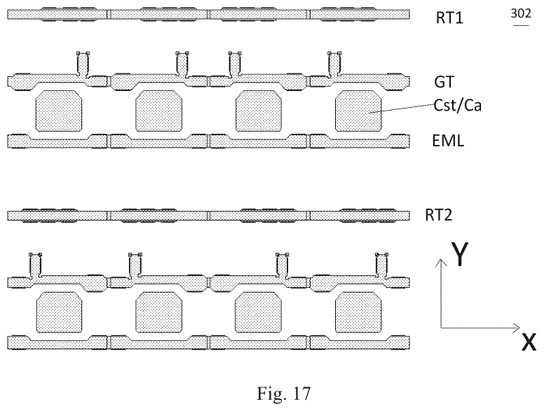

For example, FIG. 16 is a schematic plan view of a semiconductor pattern in another display substrate provided by at least one embodiment of the present disclosure. FIG. 17 is a schematic plan view of the first metal layer in another display substrate provided by at least one embodiment of the present disclosure. Combined with FIGS. 16 and 17, FIG. 16 shows a semiconductor layer 301, and FIG. 17 shows a first metal layer 302, for example, a first gate insulating layer is provided between the first metal layer 302 and the semiconductor layer 301. For example, a semiconductor layer 301 and subsequent various components are formed on a base substrate 1011 (shown in FIGS. 3A and 3B).

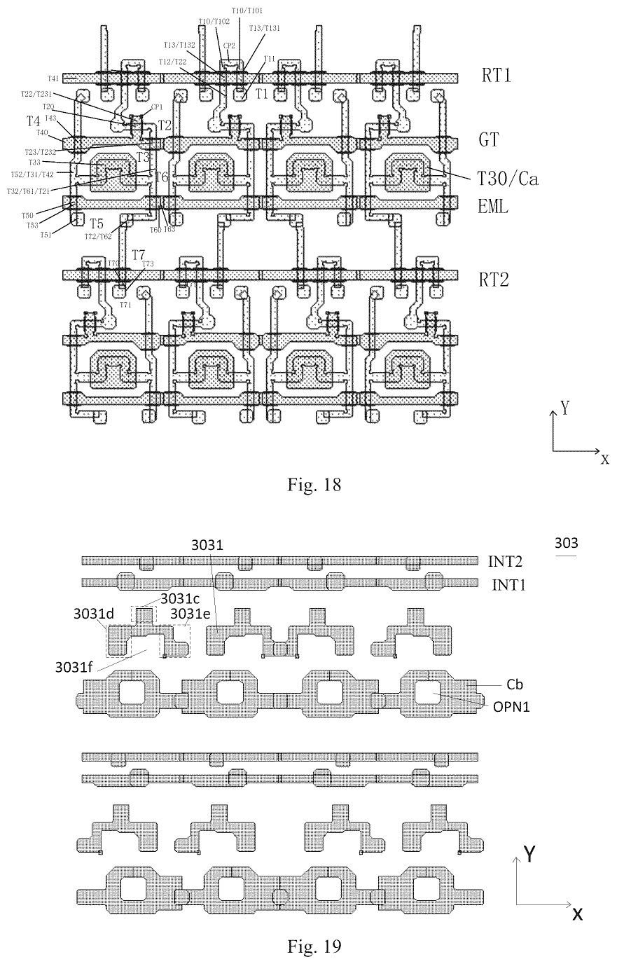

For example, as illustrated by FIG. 17, the first metal layer 302 includes a first reset control signal line RT1, a gate signal line GT, a light emission control signal line EML and a second reset control signal line RT2 extending in the first direction X and arranged in the second direction Y. The first metal layer 302 also includes a first electrode plate Ca (i.e., the gate electrode T30 of the driving transistor T3 with reference to FIG. 1) of the storage capacitor Cst, the first electrode plate Ca of the storage capacitor Cst is located between the gate signal line GT and the light emission control signal line EML in the second direction Y. The first direction X and the second direction Y intersect with each other. The semiconductor layer 301 is doped by using the first metal layer 302 as a mask, so that a region of the semiconductor layer 301 covered by the first metal layer 302 retains the semiconductor characteristics and forms an active layer (see the following FIG. 18), while a region of the semiconductor layer 301 not covered by the first metal layer 302 is conducted to form a source electrode and a drain electrode of a thin film transistor. For example, FIG. 18 is a schematic diagram of an active layer, a source electrode and a drain electrode of a thin film transistor formed in a display substrate provided by at least one embodiment of the present disclosure, that is, FIG. 18 shows the active layer formed after the semiconductor layer is partially conducted. For example, in the embodiment of the present disclosure, the gate signal line GT of the present stage is connected with the reset control signal line of the next stage. For example, the gate signal line GT and the second reset control signal line RT2 may be electrically connected and input with the same signal at the same time.

For example, as illustrated by FIGS. 17 and 18, the first reset control signal line RT1, the gate signal line GT, the light emission control signal line EML and the second reset control signal line RT2 all extend in the first direction X.

For example, as illustrated by FIG. 18, in the manufacturing process of the display substrate, the semiconductor layer 301 is subjected to a conduction treatment by using the first metal layer 302 as a mask through a self-alignment process, for example, the semiconductor layer 301 is heavily doped by using the ion implantation process, so that the part of the semiconductor layer 301 not covered by the first metal layer 302 is made conductive and forms a source region (first electrode T31) and a drain region (second electrode T32) of a driving transistor T3, a source region (first electrode T41) and a drain region (second electrode T42) of a data writing transistor T4, a source region (first electrode T21) and a drain region (second electrode T22) of a threshold compensation transistor T2, and a source region (first electrode T51) and a drain region (second electrode T52) of a first light emission control transistor T5, a source region (first electrode T61) and a drain region (second electrode T62) of a second light emission control transistor T6, a source region (first electrode T11) and a drain region (second electrode T12) of a first reset transistor T1, and a source region (first electrode T71) and a drain region (second electrode T72) of a second reset transistor T7. The part of the semiconductor layer 301 covered by the first metal layer 302 retains semiconductor characteristics, and forms a channel region T33 of the driving transistor T3, a channel region T43 of the data writing transistor T4, a channel region T23 of the threshold compensation transistor T2, a channel region T53 of the first light emission control transistor T5, a channel region T63 of the second light emission control transistor T6, a channel region T13 of the first reset transistor T1, and a channel region T73 of the second reset transistor T7. The channel region of each transistor constitutes an active layer.

For example, as illustrated by FIG. 18, the second electrode T72 of the second reset transistor T7 and the second electrode T62 of the second light emission control transistor T6 are integrally formed; the first electrode T61 of the second light emission control transistor T6, the second electrode T32 of the driving transistor T3 and the first electrode T21 of the threshold compensation transistor T2 are integrally formed; the first electrode T31 of the driving transistor T3, the second electrode T42 of the data writing transistor T4 and the second electrode T52 of the first light emission control transistor T5 are integrally formed; and the second electrode T22 of the threshold compensation transistor T2 and the second electrode T12 of the first reset transistor T1 are integrally formed.

For example, the channel region (active layer) of the transistor adopted by the embodiment of the present disclosure may be monocrystalline silicon, polycrystalline silicon (such as low-temperature polycrystalline silicon) or metal oxide semiconductor materials (such as IGZO, AZO, etc.). In one embodiment, the transistors are all P-type low temperature polysilicon (LTPS) thin film transistors. In another embodiment, the threshold compensation transistor T2 and the first reset transistor T1 directly connected with the gate electrode of the driving transistor T3 are metal oxide semiconductor thin film transistors, that is, the channel materials of the transistors are metal oxide semiconductor materials (such as IGZO, AZO, etc.), and the metal oxide semiconductor thin film transistors have lower leakage current, which can help to reduce the gate leakage current of the driving transistor T3.

For example, the transistor adopted by the embodiment of the present disclosure may include various structures, such as a top gate type, a bottom gate type or a double-gate structure. In some embodiments, the threshold compensation transistor T2 and the first reset transistor T1, which are directly connected with the gate electrode of the driving transistor T3, are double-gate type thin film transistors, which can help reduce the gate leakage current of the driving transistor T3.

For example, as illustrated by FIG. 18, a part of the light emission control signal line EML serves as the gate electrode T50 of the first light emission control transistor T5, a part of the light emission control signal line EML serves as the gate electrode T60 of the second light emission control transistor T6, the gate electrode T10 of the first reset transistor T1 is a part of the first reset control signal line RT1, the gate electrode T70 of the second reset transistor T7 is a part of the second reset control signal line RT2, the gate electrode T40 of the data writing transistor T4 is a part of the gate signal line GT, and the gate electrode T20 of the threshold compensation transistor T2 is a part of the gate signal line GT.

For example, as illustrated by FIG. 18, the threshold compensation transistor T2 is a double-gate type thin film transistor, and the threshold compensation transistor T2 includes a first channel T231 and a second channel T232, the first channel T231 and the second channel T232 are connected by a first conductive connection CP1. For example, an orthographic projection of the first conductive connection CP1 on the base substrate 1011 at least partially overlaps with an orthographic projection of a conducted active layer between the two gate electrodes T20 of the threshold compensation transistor T2 on the base substrate 1011.

For example, as illustrated by FIG. 18, the first reset transistor T1 is a double-gate type thin film transistor, and the first reset transistor T1 includes a first channel T131 and a second channel T132, which are connected by a second conductive connection part CP2. For example, an orthographic projection of the second conductive connection part CP2 on the base substrate 1011 at least partially overlaps with an orthographic projection of a conducted active layer between the two gate electrodes T10 of the first reset transistor T1 on the base substrate 1011.

For example, FIG. 19 is a schematic plan view of a second metal layer in a display substrate provided by at least one embodiment of the present disclosure. For example, as illustrated by FIG. 19, a second gate insulating layer is provided between the second metal layer 303 and the first metal layer 302. The second metal layer 303 includes a shielding block 3031, a first initialization signal line INT1, a second initialization signal line INT2, and a second electrode plate Cb of the storage capacitor Cst. For example, referring to FIG. 19, the first initialization signal line INT1 extends in the first direction X, and the second initialization signal line INT2 extends in the first direction X. The first initialization signal line INT1 and the second initialization signal line INT2 are arranged in the second direction Y. As illustrated by FIG. 19, the first initialization signal line INT1 and the second initialization signal line INT2 are located on a same side of the second electrode plate Cb of the storage capacitor Cst, and the first initialization signal line INT1 and the second initialization signal line INT2 are located on a same side of the shielding block 3031. As illustrated by FIG. 19, the second initialization signal line INT2, the first initialization signal line INT1, the shielding block 3031 and the second electrode plate Cb of the storage capacitor Cst are sequentially arranged in the second direction Y. The shielding block 3031 is electrically connected with the first power supply line VDD1 (located in the second conductive layer mentioned later), so that the first power supply line VDD1 provides a constant voltage for the shielding block 3031.

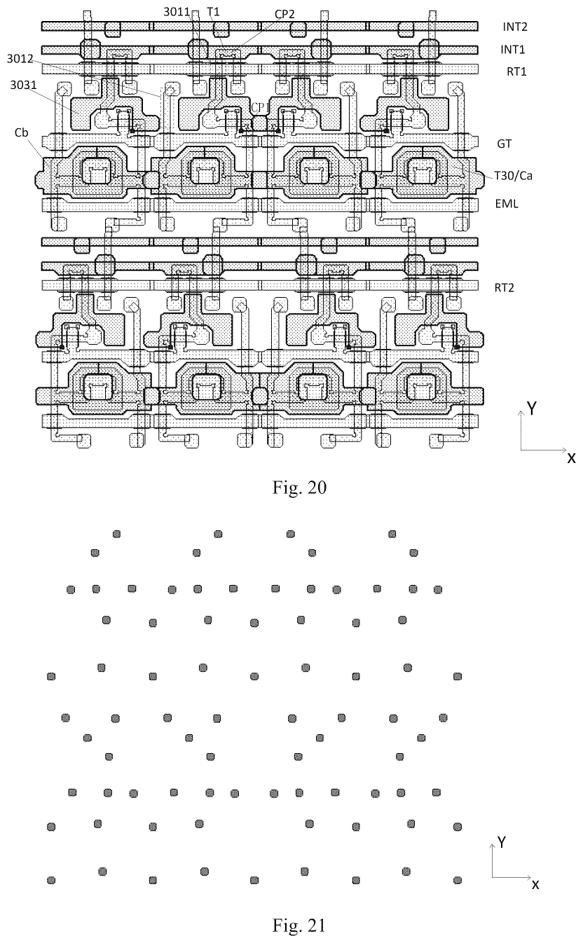

For example, FIG. 20 is a schematic plan view of a display substrate provided by at least one embodiment of the present disclosure after a second metal layer is formed. For example, as illustrated by FIG. 20, an orthographic projection of the shielding block 3031 on the base substrate 1011 at least partially overlaps with an orthographic projection of the first conductive connection part CP1 on the base substrate 1011. That is, the shielding block 3031 is configured to shield the conducted active layer, that is, the first conductive connection part CP1, between the two gate electrodes of the threshold compensation transistor T2, and the shielding block 3031 and the first conductive connection part CP1 form a capacitance (stable capacitance) to form a stable capacitance to reduce the leakage current, thereby avoiding the threshold compensation transistor T2 from generating the leakage current and avoiding affecting the display effect.

For example, in the plan view shown in FIG. 19, the shielding block 3031 partially overlaps with the first conductive connection part CP1, that is, the shielding block 3031 partially overlaps with the conducted active layer between the two gate electrodes T20 of the threshold compensation transistor T2, and the shielding block 3031 is connected with the data line (located on the second conductive layer mentioned later), so that parasitic capacitance between the data line and the gate electrode T20 of the threshold compensation transistor T2 can be shielded to reduce longitudinal crosstalk.

For example, in the plan view shown in FIG. 20, the first initialization signal line INT1 at least partially overlaps with the second conductive connection part CP2, and a capacitance (stable capacitance) is formed between the first initialization signal line INT1 and the second conductive connection part CP2 to avoid leakage current of the first reset transistor T1 and avoid affecting the display effect.

For example, as illustrated by FIG. 20, the gate signal line GT extends in the first direction X, the first reset control signal line RT1 extends in the first direction X, and the shielding block 3031 is located between the gate signal line GT and the first reset control signal line RT1, so that the position of the shielding block 3031 in the second direction Y is defined.

For example, as illustrated by FIG. 19 and FIG. 20, an orthographic projection of at least part of the shielding block 3031 on the base substrate 1011 overlaps with the orthographic projection of the first connection part 3011 on the base substrate 1011. The first connection part 3011 is connected with the gate electrode T30 of the driving transistor T3, and the orthographic projection of the first connection part 3011 on the base substrate 1011 at least partially overlaps with the orthographic projection of the shielding block 3031 on the base substrate 1011, so that the shielding block 3031 shields the parasitic capacitance between the gate electrode of the driving transistor T3 and the data line, reduces the coupling influence and reduces the longitudinal crosstalk.

For example, as illustrated by FIG. 19 and FIG. 20, the shielding block 3031 includes a first shielding part 3031c extending in a straight line in the second direction Y, and a second shielding part 3031d and a third shielding part 3031e extending in zigzag lines, the second shielding part 3031d and the third shielding part 3031e are connected at the end position of the first shielding part 3031c close to the second shielding part 3031d, and the second shielding part 3031d and the third shielding part 3031e form an accommodating space 3031f so that a part of the first connection part 3011 is in the accommodating space 3031f, and an orthographic projection of another part of the first connection part 3011 on the base substrate 1011 overlaps with the orthographic projection of the first shielding part 3031c on the base substrate 1011.

For example, as illustrated by FIG. 19, the overall shape of the shielding block 3031 is a cup cover shape, and the second shielding part 3031d and the third shielding part 3031e are not completely symmetrical.

For example, as illustrated by FIG. 18 and FIG. 20, the pixel circuit further includes a threshold compensation transistor T2, and an orthographic projection of the third shielding part 3031e on the base substrate 1011 overlaps with the orthographic projection of a conducted active layer between the two gate electrodes of the threshold compensation transistor T2 on the base substrate 1011.

For example, the material of the first connection part 3011 is the same as that of the first conductive connection part CP1. For example, the first connection part 3011 and the first conductive connection part CP1 can be made of the same film layer through the same process. For example, the material of the first connection part 3011 includes a conductive material formed by doping a semiconductor material. For example, the material of the first connection part 3011 includes a conductive material formed by doping polysilicon, but the present embodiment is not limited thereto.

For example, as illustrated by FIGS. 18 and 20, the first connection part 3011 is multiplexed as the second electrode T12 of the first reset transistor T1, and an orthographic projection of the second electrode T12 of the first reset transistor T1 on the base substrate 1011 at least partially overlaps with an orthographic projection of the shielding block 3031 on the base substrate 1011. In the embodiment of the present disclosure, the first connection part 3011 is taken as the second electrode T12 of the first reset transistor T1 as an example.

For example, as illustrated by FIGS. 19 and 20, a third overlapping area of the orthographic projection of another part of the first connection part 3011 and the orthographic projection of the first shielding part 3031c on the base substrate is larger than a fourth overlapping area of the orthographic projection of the third shielding part 3031e on the base substrate 1011 and the orthographic projection of the conducted active layer between the two gate electrodes of the threshold compensation transistor T2 on the base substrate 1011.

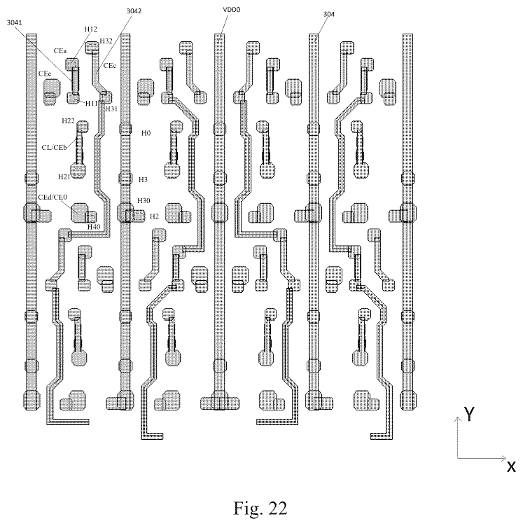

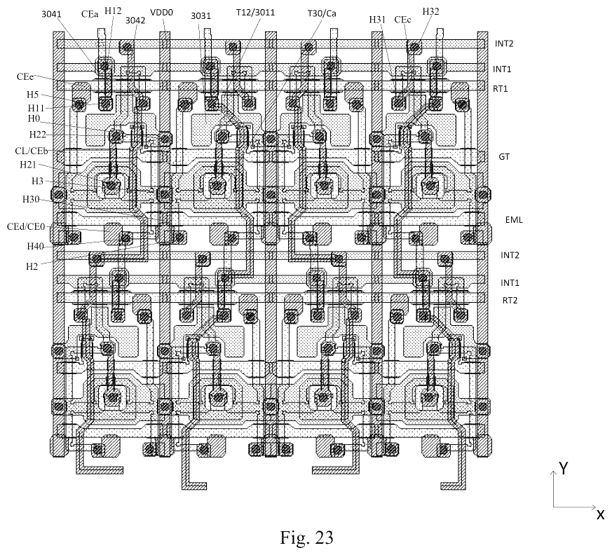

For example, FIG. 21 is a schematic plan view of via holes formed in at least one of a first gate insulating layer, a second gate insulating layer and an interlayer insulating layer in another display substrate provided by at least one embodiment of the present disclosure. FIG. 22 is a schematic plan view of the first conductive layer in another display substrate provided by at least one embodiment of the present disclosure. FIG. 23 is a schematic plan view of another display substrate provided by at least one embodiment of the present disclosure after the first conductive layer is formed.

For example, with reference to FIGS. 22 and 23, the first conductive layer 304 includes a power connection line VDD0, a connection electrode CEa, a connection electrode CEb, a connection electrode CEc, a connection electrode CEd and a connection electrode CEe. An interlayer insulating layer (for example, an interlayer insulating layer ILD) is provided between the first conductive layer 304 and the second metal layer 303.

For example, as illustrated by FIGS. 22 and 23, the first conductive layer 304 includes a first connection structure 3041 and a second connection structure 3042 spaced apart from each other. A first end of the first connection structure 3041 is electrically connected with the first initialization signal line INT1 and the first connection structure 3041 extends in the second direction Y, a first end of the second connection structure 3042 is electrically connected with the first initialization signal line INT1, and the second connection structure 3042 extends in the second direction.

For example, as illustrated by FIG. 22, the first connection structure 3041 is the connection electrode CEa.

For example, as illustrated by FIGS. 19 and 22, an orthographic projection of at least part of the first shielding part 3031c on the base substrate 1011 is located between the orthographic projection of the first connection structure 3041 on the base substrate 1011 and the orthographic projection of the second connection structure 3042 on the base substrate 1011. A second end of the first connection structure 3042 extends to a side of the second shielding part 3031d or the third shielding part 3031e close to the first shielding part 3031c in the second direction Y.

For example, as illustrated by FIG. 22 and FIG. 23, the power connection line VDD0 is electrically connected with the first electrode T51 of the first light emission control transistor T5 through a via hole H2, the power connection line VDD0 is electrically connected with the second electrode plate Cb of the storage capacitor Cst through the via holes H3 and H30, and the power connection line VDD0 is electrically connected with the shielding block 3031 through a via hole HO. One end of the connection electrode CEa is electrically connected with the second initialization signal line INT2 through a via hole H12, and the other end of the connection electrode CEa is connected with the first electrode T11 of the first reset transistor T1 through a via hole H11, so that the first electrode T11 of the first reset transistor T1 is electrically connected with the second initialization signal line INT2. One end of the connection electrode CEb is electrically connected with the second electrode T12 of the first reset transistor T1 through a via hole H22, and the other end of the connection electrode CEb is electrically connected with the gate electrode T30 of the driving transistor T3 (i.e. the first electrode plate Ca of the storage capacitor Cst) through a via hole H21, so that the second electrode T12 of the first reset transistor T1 is electrically connected with the gate electrode T30 of the driving transistor T3 (i.e. the first electrode plate Ca of the storage capacitor Cst). One end of the connection electrode CEc is electrically connected with the first initialization signal line INT1 through a via hole H32, and the other end of the connection electrode CEc is connected with the first electrode T71 of the second reset transistor T7 through a via hole H31, so that the first electrode T71 of the second reset transistor T7 is electrically connected with the first initialization signal line INT1. The connection electrode CEd is electrically connected with the second electrode T62 of the second light emission control transistor T6 through a via hole H40. The connection electrode CEd can be used to be connected with a connection electrode CEf formed later, and then be electrically connected with the first electrode 201 of the light emitting element 20. The connection electrode CEe is electrically connected with the first electrode T41 of the data writing transistor T4 through a via hole H5. The connection electrode CEe is used to be connected with the data line.

For example, with reference to FIGS. 16 to 23, the semiconductor layer 301 includes a first connection part 3011, in the second direction Y, an orthographic projection of the first connection part 3011 on the base substrate 1011 is located between the orthographic projection of the first reset control signal line RT1 on the base substrate 1011 and the orthographic projection of the gate signal line GT on the base substrate 1011. One end of the first connection part 3011 is electrically connected with the first electrode T11 of the first reset transistor T1, and extends in the second direction Y; in the first direction, the orthographic projection of the first connection part 3011 on the base substrate 1011 is located between the orthographic projection of the first connection structure 3041 on the base substrate 1011 and the orthographic projection of the second connection structure 3042 on the base substrate 1011. This design can reduce the longitudinal crosstalk. For example, the first connection part 3011 is an equipotential structure of the gate electrode of the driving transistor T3.

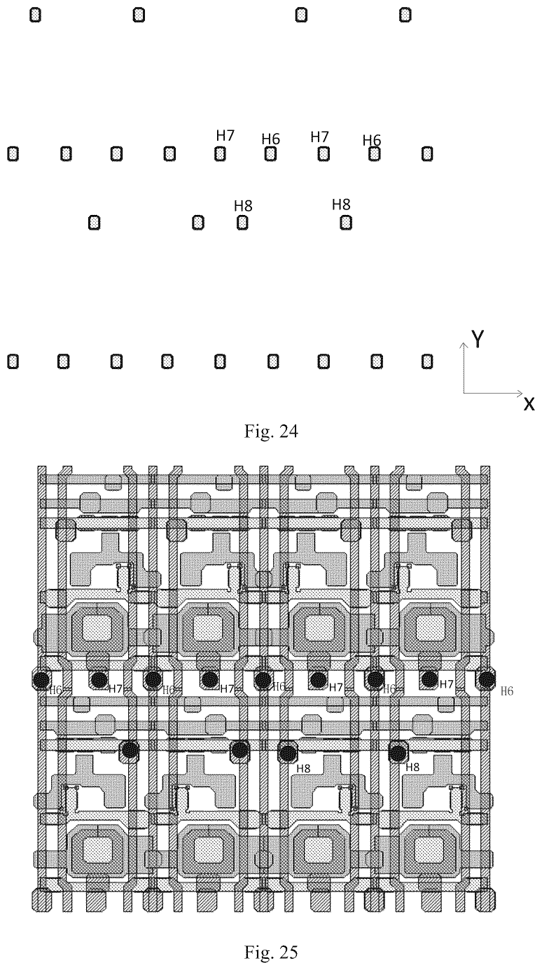

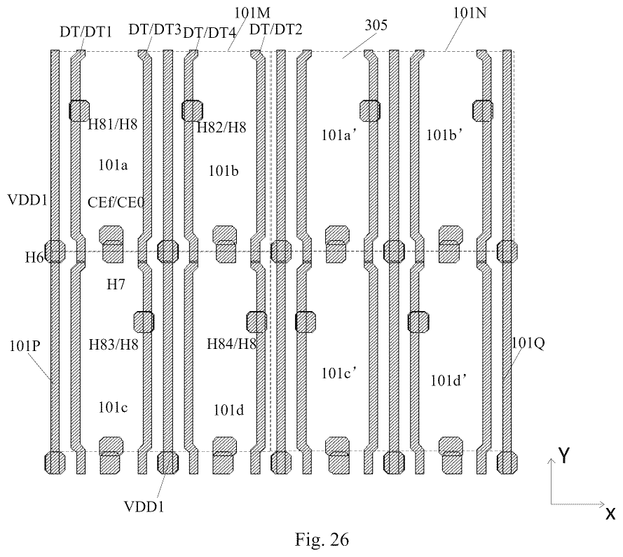

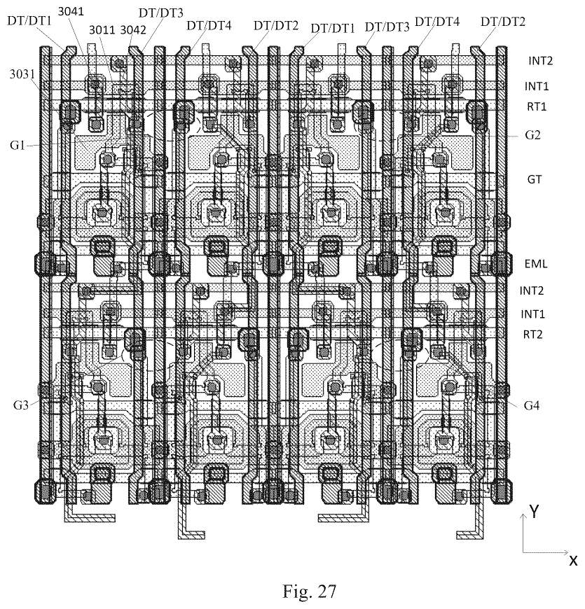

For example, FIG. 24 is a schematic plan view of via holes formed in a passivation layer and a first planarization layer in a display substrate provided by at least one embodiment of the present disclosure; FIG. 25 is a schematic diagram of a planar structure of a display substrate provided by at least one embodiment of the present disclosure after via holes are formed in a passivation layer and a first planarization layer; FIG. 26 is a schematic plan view of a second conductive layer in a display substrate provided by at least one embodiment of the present disclosure; FIG. 27 is a schematic plan view of a display substrate provided by at least one embodiment of the present disclosure after a second conductive layer is formed.

For example, with reference to FIGS. 24 to 27, the second conductive layer 305 includes data lines DT, connection electrodes CEf, and first power supply lines VDD1. The data lines DT extend in the second direction Y, and the data lines DT are configured to provide data signals to the pixel circuits. The pixel units include two adjacent pixel units located in the same column, and the two adjacent data lines DT are connected with the two adjacent pixel units respectively. A passivation layer (passivation layer PVX, referring to the subsequent schematic cross-sectional structure) and a first planarization layer (first planarization layer PLN1, referring to the subsequent schematic cross-sectional structure) are arranged between the first conductive layer 304 and the second conductive layer 305. The first power supply lines VDD1 are connected with the power supply connection line VDD0 through via holes H6 penetrating the passivation layer and the first planarization layer, and the connection electrodes CEf are connected with the connection electrodes CEd through via holes H7 penetrating the passivation layer and the first planarization layer. The data lines DT are connected with the connection electrodes CEe through via holes H8 penetrating through the passivation layer and the first planarization layer, and are further electrically connected with the first electrodes T41 of the data writing transistors T4. For example, the connection electrode CEf and the connection electrode CEd constitute a connection element CEO. For example, the light emitting element 20 is connected with the pixel circuit 10 through the connection element CEO. For example, the pixel circuit 10 is connected with the connection electrode CEd, the connection electrode CEd is connected with the connection electrode CEf, and the connection electrode CEf is connected with the light emitting element 20.

For example, with reference to FIGS. 23 to 26, the first power supply line VDD1 is connected with the second electrode plate Cb of the storage capacitor Cst through the power supply connection line VDD0.

For example, with reference to FIGS. 19 to 26, an orthographic projection of the first shielding part 3031c on the base substrate 1011 overlaps with the orthographic projection of the data line DT on the base substrate 1011.

For example, as illustrated by FIG. 26, two rows of pixel units 101 in the second direction Y and four columns of pixel units 101 in the first direction X form a repeating unit, and the pixel unit 101 in a first row and a first column and the pixel unit 101 in the first row and a second column form a first pixel unit group 101M; the pixel unit 101 in the first row and a third column and the pixel unit 101 in the first row and a fourth column form a second pixel unit group 101N; the pixel unit 101 in a second row and the first column and the pixel unit 101 in the second row and the second column form a third pixel unit group 101P; the pixel unit 101 in the second row and the third column and the pixel unit 101 in the second row and the fourth column form a fourth pixel unit group 101Q, the first pixel unit group and the second pixel unit group are symmetrical about a straight line extending in the second direction Y, and the third pixel unit group 101P and the fourth pixel unit group 101Q are symmetrical about a straight line extending in the second direction Y.

For example, FIG. 26 shows a first data line DT1, a second data line DT2, a third data line DT3 and a fourth data line DT4. FIG. 26 also shows the positions of the first pixel unit 101a, the second pixel unit 101b, the third pixel unit 101c and the fourth pixel unit 101d. Actually, eight pixel units are shown in FIG. 26, and the whole composed of the pixel unit 101a′, the pixel unit 101b′, the pixel unit 101c′ and the pixel unit 101d′ is symmetrical with the whole composed of the first pixel unit 101a, the second pixel unit 101b, the third pixel unit 101c and the fourth pixel unit 101d about the Y axis (i.e. the second direction).

For example, as illustrated by FIG. 27, a planar shape of the third shielding part 3031e in the first pixel unit group 101M includes an “L” shape, the planar shape of the third shielding part 303e in the second pixel unit group 101N includes an inverted “L” shape, and a part of the third shielding part 303e having an “L” shape and extending in the second direction in the first pixel unit group 101M is connected with a part of the third shielding part 3031e having an inverted “L” shape and extending in the second direction in the second pixel unit group 101N.

For example, as illustrated by FIG. 27, the two adjacent shielding blocks 3031 of the first pixel unit group 101M and the second pixel unit group 101N are connected with each other, and the two adjacent shielding blocks 3031 of the third pixel unit group 101P and the fourth pixel unit group 101Q are spaced apart from each other, that is, the two adjacent shielding blocks 3031 of the first pixel unit group 101M and the second pixel unit group 101N are connected into a whole structure, and the two adjacent shielding blocks 3031 of the third pixel unit group 101P and the fourth pixel unit group 101Q are not connected as a whole.

For example, as illustrated by FIG. 27, the second shielding part 3031d of the shielding block 3031 of the third pixel unit group 101P that is adjacent to the fourth pixel unit group 101Q and the second shielding part 3031d of the shielding block 3031 of the fourth pixel unit group 101Q that is adjacent to the third pixel unit group 101P are adjacent to each other.

It should be noted that, in other examples, two shielding blocks 3031 in the first pixel unit group 101M may be connected with each other, two shielding blocks 3031 in the second pixel unit group 101N may be connected with each other, and two adjacent shielding blocks 3031 in the first pixel unit group 101M and the second pixel unit group 101N may also be connected with each other; two shielding blocks 3031 in the third pixel unit group 101P may be connected with each other, two shielding blocks 3031 in the fourth pixel unit group 101Q may be connected with each other, and two adjacent shielding blocks 3031 in the third pixel unit group 101P and the fourth pixel unit group 101Q may also be connected with each other, that is, they may be connected to form an elongated shape.

For example, in an example, as illustrated by FIG. 3B, FIG. 26 and FIG. 27, in the first pixel unit group 101M, a first gap G1 exists between two adjacent shielding blocks 3031, and an orthographic projection of at least one data line DT on the base substrate 1011 is located in an orthographic projection of the first gap G1 on the base substrate 1011. For example, in FIG. 26, an orthographic projection of the data line DT4 on the base substrate 1011 is located in the orthographic projection of the first gap G1 on the base substrate 1011. In the second pixel unit group 101N, a second gap G2 exists between two adjacent shielding blocks 3031, and an orthographic projection of at least one data line DT on the base substrate 1011 is located in an orthographic projection of the second gap G2 on the base substrate 1011. For example, in FIG. 26, an orthographic projection of the data line DT3 on the base substrate 1011 is located in the orthographic projection of the second gap G2 on the base substrate 1011. In the third pixel unit group 101P, a third gap G3 exists between two adjacent shielding blocks 3031, and an orthographic projection of at least one data line DT on the base substrate 1011 is located in an orthographic projection of the third gap G3 on the base substrate 1011. For example, in FIG. 26, an orthographic projection of the data line DT3 on the base substrate 1011 is located in the orthographic projection of the third gap G3 on the base substrate 1011. In the fourth pixel unit group 101Q, a fourth gap G4 exists between two adjacent shielding blocks 3031, and an orthographic projection of at least one data line DT on the base substrate 1011 is located in an orthographic projection of the fourth gap G4 on the base substrate 1011. For example, in FIG. 26, an orthographic projection of the data line DT4 on the base substrate 1011 is located in the orthographic projection of the fourth gap G4 on the base substrate 1011. For example, setting the data line DT in the corresponding gap can reduce the overlapping area between the data line DT and the shielding block 3031, thereby reducing the load of the corresponding data line.

For example, as illustrated by FIG. 26 and FIG. 27, the second connection structure 3042 corresponding to the pixel unit 101a in the first row and the first column and the second connection structure 3042 corresponding to the pixel unit 101c in the second row and the first column are connected into an integrated structure to form a first column connector; the first connection structure 3042 corresponding to the pixel unit 101b in the first row and the second column and the first connection structure 3042 corresponding to the pixel unit 101d in the second row and the second column are connected into an integrated structure to form a second column connector; the second connection structure 3042 corresponding to the pixel unit 101a′ in the first row and the third column and the second connection structure 3042 corresponding to the pixel unit 101c′ in the second row and the third column are connected into an integrated structure to form a third column connector; the first connection structure 3042 corresponding to the pixel unit 101b′ in the first row and the fourth column and the first connection structure 3042 corresponding to the pixel unit 101d′ in the second row and the fourth column are connected into an integrated structure to form a fourth column connector; the first column connector and the third column connector are symmetrical about a straight line extending in the second direction Y, and the second column connector and the fourth column connector are symmetrical about a straight line extending in the second direction Y. This symmetrical design can make the structural design of the first conductive layer in the display substrate simpler, and the first column connector, the second column connector, the third column connector and the fourth column connector are all strip-shaped structures, which can reduce the risk of electrical connection failure caused by disconnection.

For example, as illustrated by FIG. 27, the first column connector, the second column connector, the third column connector and the fourth column connector all bend and extend in the second direction Y, and the first column connector, the second column connector, the third column connector and the fourth column connector respectively correspond to a plurality of pixel units 101 located in the same column.

For example, as illustrated by FIG. 27, the second connection structure 3042 is electrically connected with at least two adjacent first initialization signal lines INT1, so that the first initialization signal lines INT1 and the second connection structure 3042 intersect with each other to form a grid-like structure, which can further improve the display quality of the display substrate.

For example, with reference to FIGS. 1, 3B and 26, the first power supply line VDD1 is configured to provide the first voltage signal ELVDD to the pixel circuit 10. The first power supply line VDD1 is electrically connected with the shielding block 3031 to provide a constant voltage for the shielding block 3031. The first power supply line VDD1 is connected with the first power supply terminal VDD, and the second electrode plate Cb of the storage capacitor Cst is connected with the first power supply line VDD1. For example, the second electrode plate Cb of the storage capacitor Cst is connected with the first power supply terminal VDD through the power supply connection line VDD0 and the first power supply line VDD1.

For example, the first electrode T51 of the first light emission control transistor T5 is connected with the first power supply terminal VDD through the power supply connection line VDD0 and the first power supply line VDD1.

For example, as illustrated by FIG. 20 and FIG. 27, the area of an orthographic projection of a part of the shielding block 3031 overlapping with the first connection part 3011 on the base substrate 1011 is larger than the area of an orthographic projection of the part of the shielding block 3031 overlapping with the first conductive connection part CP1 on the base substrate 1011, but the embodiment of the present disclosure is not limited thereto.

For example, as illustrated by FIG. 27, the orthographic projection of the shielding block 3031 on the base substrate 1011 partially overlaps with the orthographic projection of the third data line DT3 on the base substrate 1011, so that the shielding block 3031 shields the interference between the first data signal on the first data line DT1 and the third data signal on the third data line DT3, and avoids display abnormality caused by coupling. For example, in the planar structure diagram shown in FIG. 27, one shielding block 3031 corresponds to two pixel units in the same row. As illustrated by FIG. 27, at least a part of the shielding block 3031 is located between the first data line DT1 and the second data line DT3.

For example, in the embodiment of the present disclosure, two adjacent elements refer to that the two elements are adjacent to each other, and there is no element between them, but it is not excluded that other elements other than such elements are arranged between the two adjacent elements.

For example, in the embodiment of the present disclosure, the preparation process of the display substrate is provided as follows: pixel circuits are formed on the base substrate 1011 to form the display substrate shown in FIG. 15 or FIG. 27, and light emitting elements are formed on the basis of the display substrate shown in FIG. 15 or FIG. 27 to obtain the display substrate, so that the pixel circuits are closer to the base substrate than the light emitting elements.

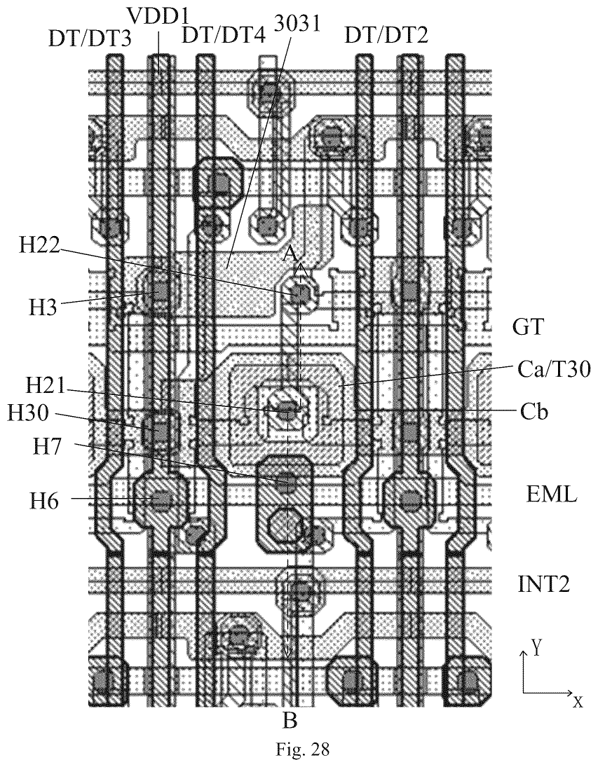

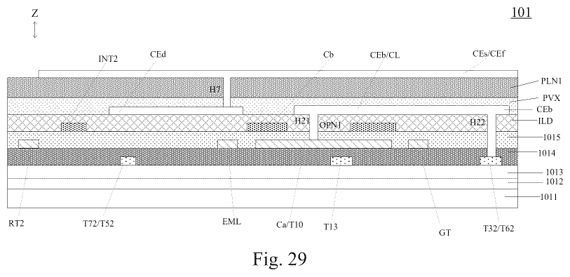

For example, FIG. 28 is a partially enlarged structural schematic diagram of the display substrate shown in FIG. 15, and FIG. 29 is a sectional structural schematic diagram of the display substrate shown in FIG. 28 along a line AB.

For example, in FIG. 29, the film layers above the first electrode 201 of the light emitting element are omitted. The structure of each layer above the first electrode 201 of the light emitting element 20 can refer to the conventional design, and those skilled in the art can adjust the setting position and shape of the first electrode 201 of the light emitting element as needed.

For example, as illustrated by FIG. 29, both the first direction X and the second direction Y are directions parallel to the base substrate 1011. For example, the first direction X is perpendicular to the second direction Y. FIG. 29 shows a third direction Z, the third direction Z is a direction perpendicular to a main surface of the base substrate 1011. The third direction Z is perpendicular to the first direction X and the second direction Y. A buffer layer 1012 is arranged on the base substrate 1011, and an isolation layer 1013 is located on the buffer layer 1012. The channel region, the source electrode and the drain electrode of each of the transistors are located on the isolation layer 1013, and a first gate insulating layer 1014 is formed on the channel region, the source electrode and the drain electrode of each of the transistors, a first metal layer is located on the first gate insulating layer 1014, a second gate insulating layer 1015 is located on the first metal layer, a second metal layer is located on the second metal layer, an interlayer insulating layer ILD is located on the second metal layer, a first conductive layer is located on the interlayer insulating layer ILD, a passivation layer PVX is located on the first metal layer, a first planarization layer PLN1 is located on the passivation layer PVX, and a second conductive layer is located on the first planarization layer PLN1.

For example, the light emitting element may refer to a conventional structure, and the light emitting element may include an organic light emitting diode. The light emitting functional layer is located between the second electrode and the first electrode. The second electrode is located at a side of the first electrode away from the base substrate, and the light emitting functional layer at least includes a light emitting layer, and may also include at least one of a hole transport layer, a hole injection layer, an electron transport layer and an electron injection layer.

For example, the transistors in the pixel circuit of the embodiment of the present disclosure are all thin film transistors. For example, the first metal layer, the second metal layer, the first conductive layer and the second conductive layer are all made of metal materials. For example, both the first metal layer and the second metal layer are formed of metal materials such as nickel and aluminum, but the embodiments of the present disclosure are not limited thereto. For example, the first conductive layer and the second conductive layer are formed of materials such as titanium and aluminum, but the embodiments of the present disclosure are not limited thereto. For example, the first conductive layer and the second conductive layer are structures formed by three sub-layers of Ti/AL/Ti, respectively, but the embodiment of the present disclosure is not limited thereto. For example, the base substrate can be a glass substrate or a polyimide substrate, but the embodiment of the present disclosure is not limited thereto and can be selected as required. For example, the first gate insulating layer 1014, the second gate insulating layer 1015, the interlayer insulating layer ILD, the passivation layer PVX, the first planarization layer PLN1 and the second planarization layer PLN2 are all made of insulating materials.

For example, the materials of the first electrode and the second electrode of the light emitting element can be selected as required. In some embodiments of the present disclosure, the first electrode may adopt at least one of transparent conductive metal oxide and silver, but the embodiments of the present disclosure are not limited thereto. For example, the transparent conductive metal oxide includes indium tin oxide (ITO), but embodiments of the present disclosure are not limited thereto. For example, the first electrode may adopt a structure in which three sublayers of ITO-Ag-ITO are arranged. In some embodiments, the second electrode may be a metal with a low work function, and at least one of magnesium and silver may be used, but the embodiments of the present disclosure are not limited thereto.

At least one embodiment of the present disclosure further provides a display device, and the display device includes any one of the display substrates. For example, the display device includes an OLED or a product driven by a high frame rate including an OLED. For example, the display device includes a TV, a digital camera, a mobile phone, a watch, a tablet computer, a notebook computer, a navigator and other products or components with a display function.

The above description takes the pixel circuit of 7T1C as an example, and embodiments of the present disclosure include but are not limited thereto. It should be noted that the embodiment of the present disclosure does not limit the number of thin film transistors and the number of capacitors included in the pixel circuit. For example, in other embodiments, the pixel circuit of the display substrate can also be a structure including other numbers of transistors, such as a 7T2C structure, a 6T1C structure, a 6T2C structure or a 9T2C structure, which is not limited by the embodiment of the present disclosure.

In the embodiment of the present disclosure, elements located in the same layer can be formed in the same patterning process from the same film layer. For example, elements located in the same layer may be located on the surface of the same element away from the base substrate.

In an embodiment of the present disclosure, the patterning or the patterning process may only include a photolithography process, or a photolithography process and an etching step, or may include printing, inkjet and other processes for forming a predetermined pattern. Lithography process refers to the process including film formation, exposure and development, and the pattern is formed by using a photoresist, a mask plate and an exposure machine. A corresponding patterning process can be selected according to the structure formed in the embodiment of the present disclosure.

The following statements should be noted:

(1) The accompanying drawings involve only the structure(s) in connection with the embodiment(s) of the present disclosure, and other structure(s) can be referred to common design(s).

(2) In case of no conflict, the embodiments of the present disclosure and the features in the embodiments can be combined with each other to obtain new embodiments.

The above is only the specific embodiment of this disclosure, but the protection scope of this disclosure is not limited to this. All the changes or substitutions, that can be easily thought of by any person familiar with the technical field within the technical scope disclosed in this disclosure, should be included in the protection scope of this disclosure. Therefore, the scope of protection of this disclosure should be based on the scope of protection of the claims.

1. A display substrate, comprising:
a base substrate; and
a pixel unit, located on the base substrate and comprising a pixel circuit, wherein the pixel circuit comprises a first reset transistor;
wherein the display substrate further comprises a semiconductor layer, a first metal layer, a second metal layer and a first conductive layer which are stacked on the base substrate,
the first metal layer comprises a first reset control signal line and a gate signal line extending in a first direction and arranged in a second direction, and the first direction and the second direction intersect with each other;
the second metal layer comprises a first initialization signal line and a second initialization signal line extending in the first direction and arranged in the second direction;
the first conductive layer comprises a first connection structure and a second connection structure spaced apart from each other, a first end of the first connection structure is electrically connected with the second initialization signal line and the first connection structure extends in the second direction, and a first end of the second connection structure is electrically connected with the first initialization signal line and the second connection structure extends in the second direction;
the semiconductor layer comprises a first connection part, in the second direction, an orthographic projection of the first connection part on the base substrate is located between an orthographic projection of the first reset control signal line on the base substrate and an orthographic projection of the gate signal line on the base substrate, and one end of the first connection part is electrically connected with a first electrode of the first reset transistor and the first connection part extends in the second direction;
in the first direction, an orthographic projection of the first connection part on the base substrate is located between an orthographic projection of the first connection structure on the base substrate and an orthographic projection of the second connection structure on the base substrate.

2. The display substrate according to claim 1, wherein the second metal layer comprises a shielding block, and an orthographic projection of at least part of the shielding block on the base substrate overlaps with the orthographic projection of the first connection part on the base substrate.

3. The display substrate according to claim 2, further comprising a second conductive layer on a side of the first conductive layer away from the base substrate, wherein the second conductive layer comprises a data line extending in the second direction, and the data line is configured to provide a data signal to the pixel circuit, and the pixel unit comprises two adjacent pixel units located in a same column, and two adjacent data lines are respectively connected with the two adjacent pixel units, and orthographic projections of the two adjacent data lines on the base substrate overlap with an orthographic projection of each of the two adjacent pixel units located in the same column on the base substrate.

4. The display substrate according to claim 3, wherein the shielding block comprises a first sub-shielding block extending in the second direction and a second sub-shielding block extending in the first direction, and an orthographic projection of the first sub-shielding block on the base substrate overlaps with an orthographic projection of the first connection part on the base substrate, and an orthographic projection of the second sub-shielding block on the base substrate overlaps with an orthographic projection of the data line on the base substrate.

5. The display substrate according to claim 4, wherein the pixel circuit further comprises a threshold compensation transistor, the threshold compensation transistor is a double-gate type thin film transistor, and the orthographic projection of the second sub-shielding block on the base substrate overlaps with an orthographic projection of a conducted active layer between two gate electrodes of the threshold compensation transistor on the base substrate.

6. The display substrate according to claim 5, wherein a first overlapping area of the orthographic projection of the first sub-shielding block on the base substrate and the orthographic projection of the first connection part on the base substrate is larger than a second overlapping area of the orthographic projection of the second sub-shielding block on the base substrate and the orthographic projection of the conducted active layer between the two gate electrodes of the threshold compensation transistor on the base substrate.

7. The display substrate according to claim 5, wherein two rows of pixel units in the second direction and four columns of pixel units arranged in sequence in the first direction form a repeating unit, and the pixel unit in a first row and a first column and the pixel unit in the first row and a second column form a first pixel unit group; the pixel unit in the first row and a third column and the pixel unit in the first row and a fourth column form a second pixel unit group; the pixel unit in a second row and the first column and the pixel unit in the second row and the second column form a third pixel unit group; the pixel unit in the second row and the third column and the pixel unit in the second row and the fourth column form a fourth pixel unit group, the first pixel unit group and the second pixel unit group are symmetrical about a straight line extending in the second direction, and the third pixel unit group and the fourth pixel unit group are symmetrical about a straight line extending in the second direction.

8. The display substrate according to claim 7, wherein a planar shape of the shielding block in the first pixel unit group is an inverted “L” shape, and a planar shape of the shielding block in the second pixel unit group is an “L” shape; a planar shape of the shielding block in the third pixel unit group is an “L” shape, and a planar shape of the shielding block in the fourth pixel unit group is an inverted “L” shape.

9. The display substrate according to claim 8, wherein a gap exists between two adjacent shielding blocks in the first pixel unit group and the second pixel unit group, and a connection block and a power supply voltage signal line are arranged in the gap, the connection block and the power supply voltage signal line are electrically connected, the connection block and the two adjacent shielding blocks are arranged in the same layer, and spaced from each other.

10. The display substrate according to claim 9, wherein second sub-shielding blocks of two adjacent shielding blocks in the third pixel unit group and the fourth pixel unit group are connected with each other.

11. The display substrate according to claim 4, wherein an orthographic projection of at least part of the first sub-shielding block on the base substrate is located between the orthographic projection of the first connection structure on the base substrate and the orthographic projection of the second connection structure on the base substrate.

12. The display substrate according to claim 3, wherein the shielding block comprises a first shielding part extending in a straight line in the second direction, and a second shielding part and a third shielding part extending in zigzag lines, and the second shielding part and the third shielding part are connected at an end position of the first shielding part close to the second shielding part, and the second shielding part and the third shielding part form an accommodating space so that a part of the first connection part is in the accommodating space, and an orthographic projection of another part of the first connection part on the base substrate overlaps with an orthographic projection of the first shielding part on the base substrate.

13. The display substrate according to claim 12, wherein the pixel circuit further comprises a threshold compensation transistor, the threshold compensation transistor is a double-gate type thin film transistor, and an orthographic projection of the third shielding part on the base substrate overlaps with an orthographic projection of a conducted active layer between two gate electrodes of the threshold compensation transistor on the base substrate.

14. The display substrate according to claim 13, wherein a third overlapping area of the orthographic projection of the another part of the first connection part on the base substrate and the orthographic projection of the first shielding part on the base substrate is larger than a fourth overlapping area of the orthographic projection of the third shielding part on the base substrate and the orthographic projection of the conducted active layer between the two gate electrodes of the threshold compensation transistor on the base substrate.

15. The display substrate according to claim 13, wherein two rows of pixel units arranged in sequence in the second direction and four columns of pixel units arranged in sequence in the first direction form a repeating unit, and the pixel unit in a first row and a first column and the pixel unit in the first row and a second column form a first pixel unit group; the pixel unit in the first row and a third column and the pixel unit in the first row and a fourth column form a second pixel unit group; the pixel unit in a second row and the first column and the pixel unit in the second row and the second column form a third pixel unit group; the pixel unit in the second row and the third column and the pixel unit in the second row and the fourth column form a fourth pixel unit group, the first pixel unit group and the second pixel unit group are symmetrical about a straight line extending in the second direction, and the third pixel unit group and the fourth pixel unit group are symmetrical about a straight line extending in the second direction.

16. The display substrate according to claim 15, wherein a planar shape of the third shielding part in the first pixel unit group comprises an “L” shape, a planar shape of the third shielding part in the second pixel unit group comprises an inverted “L” shape, and a part of the third shielding part in the first pixel unit group having the “L” shape and extending in the second direction is connected with a part of the third shielding part in the second pixel unit group having the inverted “L” shape and extending in the second direction.

17. The display substrate according to claim 15, wherein two adjacent shielding blocks of the first pixel unit group and the second pixel unit group are connected with each other, and two adjacent shielding blocks of the third pixel unit group and the fourth pixel unit group are spaced from each other; in the first pixel unit group, a first gap exists between the two adjacent shielding blocks, and an orthographic projection of at least one data line on the base substrate is located in an orthographic projection of the first gap on the base substrate; in the second pixel unit group, a second gap exists between the two adjacent shielding blocks, and an orthographic projection of at least one data line on the base substrate is located in an orthographic projection of the second gap on the base substrate; in the third pixel unit group, a third gap exists between the two adjacent shielding blocks, and an orthographic projection of at least one data line on the base substrate is located in an orthographic projection of the third gap on the base substrate; in the fourth pixel unit group, a fourth gap exists between two adjacent shielding blocks, and an orthographic projection of at least one data line on the base substrate is located in an orthographic projection of the fourth gap on the base substrate.

18. The display substrate according to claim 12, wherein an orthographic projection of at least part of the first shielding part on the base substrate is located between the orthographic projection of the first connection structure on the base substrate and the orthographic projection of the second connection structure on the base substrate.

19. The display substrate according to claim 18, wherein the second connection structure corresponding to the pixel unit in the first row and the first column and the second connection structure corresponding to the pixel unit in the second row and the first column are connected into an integrated structure to form a first column connector; the first connection structure corresponding to the pixel unit in the first row and the second column and the first connection structure corresponding to the pixel unit in the second row and the second column are connected into an integrated structure to form a second column connector; the second connection structure corresponding to the pixel unit in the first row and the third column and the second connection structure corresponding to the pixel unit in the second row and the third column are connected into an integrated structure to form a third column connector; the first connection structure corresponding to the pixel unit in the first row and the fourth column and the first connection structure corresponding to the pixel unit in the second row and the fourth column are connected into an integrated structure to form a fourth column connector; the first column connector and the third column connector are symmetrical about a straight line extending in the second direction, and the second column connector and the fourth column connector are symmetrical about a straight line extending in the second direction.

20. (canceled)

21. (canceled)

22. (canceled)

23. (canceled)

24. (canceled)

25. (canceled)

26. (canceled)

27. (canceled)

28. A display device, comprising the display substrate according to claim 1.
